(19) United States
(12) Patent Application Publication
(10) Pub. No.: US 2025/0142821 A1
(43) Pub. Date: May 1, 2025

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Changhan Kim, Icheon-si Gyeonggi-do (KR); In Ku KANG, Icheon-si Gyeonggi-do (KR); Eun Mee KWON, Icheon-si Gyeonggi-do (KR); Kyung Hoon MIN, Icheon-si Gyeonggi-do (KR)

(73) Assignee: SK hynix Inc., Icheon-si Gyeonggi-do (KR)

(21) Appl. No.: 18/623,793

(22) Filed: Apr. 1, 2024

(30) Foreign Application Priority Data
Oct. 25, 2023 (KR) 10-2023-0143918

(51) Int. Cl. H10B 43/27; H10B 43/35; H10B 63/00

(52) U.S. Cl. CPC H10B 43/27; H10B 43/35; H10B 63/34; H10B 63/845

(57) ABSTRACT

The present disclosure relates to a semiconductor device and a method of manufacturing the semiconductor device. A semiconductor device includes a gate stacked structure including insulating layers and conductive layers stacked alternately with each other, a first plug pattern and a second plug pattern extending in a vertical direction corresponding to a stacking direction of the gate stacked structure, first data storage layers disposed between the first plug pattern and the conductive layers and second data storage layers disposed between the second plug pattern and the conductive layers, an isolation structure extending in the vertical direction and separating the first plug pattern and the second plug pattern from each other, and insulating patterns disposed between the first data storage layers adjacent to each other in the vertical direction and the second data storage layers adjacent to each other in the vertical direction.

### CROSS-REFERENCE TO RELATED APPLICATION

The present application claims priority under 35 U.S.C. § 119(a) to Korean patent application number 10-2023-0143918 filed on Oct. 25, 2023, in the Korean Intellectual Property Office, the entire disclosure of which application is incorporated by reference herein.

### BACKGROUND

### 1. Technical Field

Various embodiments of the present disclosure relate generally to an electronic device, and more particularly, to a semiconductor device and a manufacturing method of the semiconductor device.

### 2. Related Art

Non-volatile memory devices retain stored data regardless of power on/off conditions. The increase in integration density of two-dimensional non-volatile memory devices in which memory cells are formed in a single layer over a substrate has recently been limited. Thus, three-dimensional non-volatile memory devices have been proposed in which memory cells are stacked in a vertical direction over a substrate.

A three-dimensional non-volatile memory device may include interlayer insulating layers and gate electrodes stacked alternately with each other, and channel layers passing therethrough with memory cells stacked along the channel layers. Various structures and manufacturing methods have been developed to improve the operational reliability of three-dimensional non-volatile memory devices.

### SUMMARY

According to an embodiment, a semiconductor device may include a gate stacked structure including interlayer insulating layers and conductive layers stacked alternately with each other, a first plug pattern and a second plug pattern extending in a vertical direction corresponding to a stacking direction of the gate stacked structure, first data storage layers disposed between the first plug pattern and the conductive layers and second data storage layers disposed between the second plug pattern and the conductive layers, an isolation structure extending in the vertical direction and separating the first plug pattern and the second plug pattern from each other, and insulating patterns disposed between the first data storage layers adjacent to each other in the vertical direction and the second data storage layers adjacent to each other in the vertical direction.

According to an embodiment, a method of manufacturing a semiconductor device may include forming a hole passing through at least a portion of a stacked structure including first material layers and second material layers stacked alternately with each other, forming recessed regions by etching sidewalls of the first material layers exposed through the hole to a predetermined thickness, and forming sacrificial patterns in the recessed regions, forming insulating patterns protruding further than the sidewalls of the second material layers in a direction of the hole by oxidizing the sacrificial patterns, forming a data storage layer in spaces between the insulating patterns adjacent to each other in a vertical direction, forming a plug pattern extending in the vertical direction in the hole, and forming an isolation structure passing through the plug pattern in the vertical direction and separating the plug pattern into a first plug pattern and a second plug pattern.

According to an embodiment, a method of manufacturing a semiconductor memory device may include forming a hole passing through at least a portion of a stacked structure including first material layers and second material layers stacked alternately with each other, forming protruding patterns on sidewalls of the second material layers exposed through the hole, forming insulating patterns protruding further than sidewalls of the protruding patterns in a direction of the hole in spaces between the protruding patterns adjacent to each other in a vertical direction, forming a data storage layer in spaces between the insulating patterns adjacent to each other in the vertical direction, forming a plug pattern extending in the vertical direction in the hole, and forming an isolation structure passing through the plug pattern in the vertical direction and separating the plug pattern into a first plug pattern and a second plug pattern.

According to an embodiment, a method of manufacturing a semiconductor device may include forming a hole passing through at least a portion of a stacked structure including first material layers and second material layers stacked alternately with each other, forming insulating patterns on sidewalls of the first material layers exposed through the hole, forming a data storage layer in spaces between the insulating patterns adjacent to each other in the vertical direction, forming a plug pattern extending in the vertical direction in the hole, and forming an isolation structure passing through the plug pattern in the vertical direction and separating the plug pattern into a first plug pattern and a second plug pattern.

According to an embodiment, a method of manufacturing a semiconductor device may include forming a hole having an elliptical shape passing through at least a portion of a stacked structure including first material layers and second material layers stacked alternately with each other, forming recessed regions by etching sidewalls of the first material layers exposed through the hole to a predetermined thickness, and forming sacrificial patterns in the recessed regions, forming insulating patterns protruding further than the sidewalls of the second material layers in a direction of the hole by oxidizing the sacrificial patterns, forming a data storage layer in spaces between the insulating patterns adjacent to each other in the vertical direction, sequentially forming a tunnel isolation layer and a channel layer extending in the vertical direction on a sidewall of the hole, wherein a thickness of a cross section of the channel layer in a first horizontal direction is greater than a thickness of a cross section in a second horizontal direction substantially perpendicular to the first horizontal direction, forming a first channel layer and a second channel layer by etching the channel layer to a predetermined thickness so that the channel layer is divided into the first and second channel layers in the first horizontal direction, and exposing a portion of the tunnel isolation layer through and between the first channel layer and the second channel layer, and sequentially etching an exposed portion of the tunnel isolation layer and the data storage layer to divide the tunnel isolation layer and the second isolation layer in two parts in the first horizontal direction.

According to an embodiment, a method of manufacturing a semiconductor device may include forming a stacked structure including first material layers and second material layers stacked alternately with each other, forming a first isolation pattern passing through the stacked structure in a vertical direction and extending in a first horizontal direction, forming a hole passing through the stacked structure and the first isolation pattern, forming recessed regions by etching sidewalls of the first material layers exposed through the hole to a predetermined thickness, and forming sacrificial patterns in the recessed regions, forming insulating patterns protruding further than sidewalls of the second material layers in a direction of the hole by oxidizing the sacrificial patterns, forming a data storage layer in spaces between the insulating patterns adjacent to each other in the vertical direction, sequentially forming a tunnel isolation layer, a channel layer, and a core insulating layer extending in the vertical direction on a sidewall of the hole, and forming a second isolation pattern passing through the tunnel isolation layer, the channel layer, and the core insulating in the vertical direction and separating the channel layer into a first channel layer and a second channel layer.

According to an embodiment, a method of manufacturing a semiconductor device may include forming a stacked structure including first material layers and second material layers stacked alternately with each other, forming a first isolation pattern passing through the stacked structure in a vertical direction and extending in a first horizontal direction, forming a hole passing through the stacked structure and the first isolation pattern, forming first recessed regions by etching sidewalls of the first material layers exposed through the hole to a predetermined thickness and forming sacrificial patterns in the first recessed regions, forming insulating patterns protruding further than sidewalls of the second material layers in a direction of the hole by oxidizing the sacrificial patterns, forming a data storage layer in spaces between the insulating patterns adjacent to each other in the vertical direction, sequentially forming a tunnel isolation layer, a channel layer, and a core insulating layer extending in the vertical direction on a sidewall of the hole, forming a second recessed region by removing the first isolation pattern, and separating the channel layer into a first channel layer and a second channel layer spaced apart from each other by etching the tunnel isolation layer and the channel layer exposed through the second recessed region.

According to an embodiment, a method of manufacturing a semiconductor device may include forming a stacked structure including first material layers and second material layers stacked alternately with each other, forming a first isolation pattern passing through the stacked structure in a vertical direction and extending in a first horizontal direction, forming a hole passing through the stacked structure and the first isolation pattern, forming first recessed regions by etching sidewalls of the first material layers exposed through the hole to a predetermined thickness, and forming sacrificial patterns in the first recessed regions, forming insulating patterns protruding further than the sidewalls of the second material layers in a direction of the hole by oxidizing the sacrificial patterns, forming a data storage layer in spaces between the insulating patterns adjacent to each other in the vertical direction, sequentially forming a tunnel isolation layer, a channel layer, and a core insulating layer extending in the vertical direction on a sidewall of the hole, forming a second recessed region by removing the first isolation pattern, and forming a channel isolation structure by oxidizing a portion of the channel layer adjacent to the second recessed region by performing a wet oxidation process through the second recessed region.

According to an embodiment, a method of manufacturing a semiconductor device may include forming a hole passing through at least a portion of a stacked structure including first material layers and second material layers stacked alternately with each other, forming a first isolation pattern and a second isolation pattern contacting an interface between a first sidewall and a second sidewall opposing each other in the hole, and extending in a vertical direction, forming insulating patterns on sidewalls of the first material layers exposed through the hole, removing the first isolation pattern and the second isolation pattern and forming a data storage layer in spaces between the insulating patterns adjacent to each other in the vertical direction on the first and second sidewalls, sequentially forming a tunnel isolation layer, a channel layer, and a core insulating layer on a sidewall of the hole, performing an etch process to expose a sidewall of the stacked structure, forming recessed regions by removing exposed portions of the second material layers, and forming a channel isolation structure by oxidizing a portion of the channel layer adjacent to the recessed regions by performing a wet oxidation process through the recessed regions.

### BRIEF DESCRIPTION OF THE DRAWINGS

FIGS. 1A, 1B, and 1C are a cross-sectional diagram and plan views for illustrating a semiconductor device according to an embodiment of the present disclosure;

FIGS. 2A, 2B, 2C, 2D, 2E, 2F, 2G, 2H, and 2I are cross-sectional views and plan views for illustrating a method of manufacturing a semiconductor device according to an embodiment of the present disclosure;

FIGS. 3A, 3B, 3C, 3D, 3E, 3F, and 3G are cross-sectional views and plan views for illustrating a method of manufacturing a semiconductor device according to an embodiment of the present disclosure;

FIGS. 4A, 4B, 4C, and 4D are cross-sectional views for illustrating a method of manufacturing a semiconductor device according to an embodiment of the present disclosure;

FIGS. 5A, 5B, 5C, 5D, 5E, 5F, 5G, 5H, 5I, 53, 5K, 5L, and 5M are cross-sectional views and plan views for illustrating a method of manufacturing a semiconductor device according to an embodiment of the present disclosure;

FIGS. 6A, 6B, 6C, 6D, 6E, 6F, 6G, 6H, 6I, 6J, and 6K are cross-sectional views and plan views for illustrating a method of manufacturing a semiconductor device according to an embodiment of the present disclosure;

FIGS. 7A, 7B, 7C, 7D, 7E, and 7F are plan views for illustrating a method of manufacturing a semiconductor device according to an embodiment of the present disclosure;

FIGS. 8A, 8B, 8C, 8D, 8E, and 8F are plan views for illustrating a method of manufacturing a semiconductor device according to an embodiment of the present disclosure;

FIGS. 9A, 9B, 9C, 9D, 9E, 9F, 9G, 9H, 9I, 9J, 9K, 9L, 9M, 9N, 9O, 9P, 9Q, 9R, 9S, 9T, 9U, 9V, 9W, 9X, and 9Y are cross-sectional views and plan views for illustrating a method of manufacturing a semiconductor device according to an embodiment of the present disclosure; and

FIG. 10 is a block diagram illustrating a memory system including a semiconductor device according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, embodiments of the present disclosure will be described in detail with reference to the accompanying drawings in order for those skilled in the art to be able to readily implement the technical spirit of the present disclosure.

An embodiment of the present disclosure provides a semiconductor device including a vertical structure including a plurality of plug patterns and a method of manufacturing the semiconductor device.

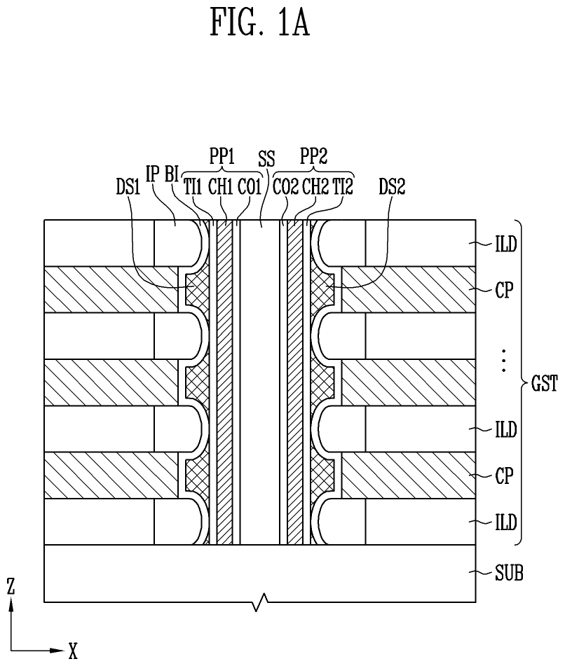

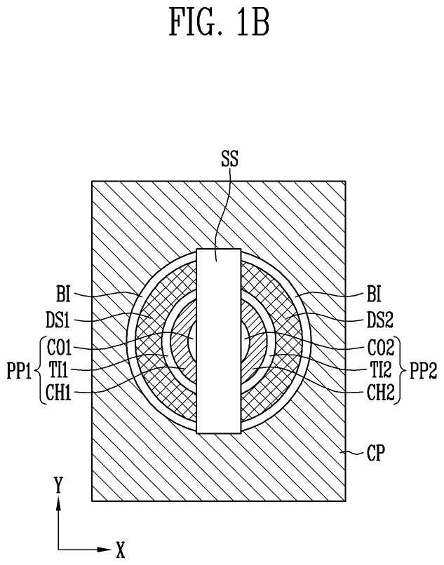

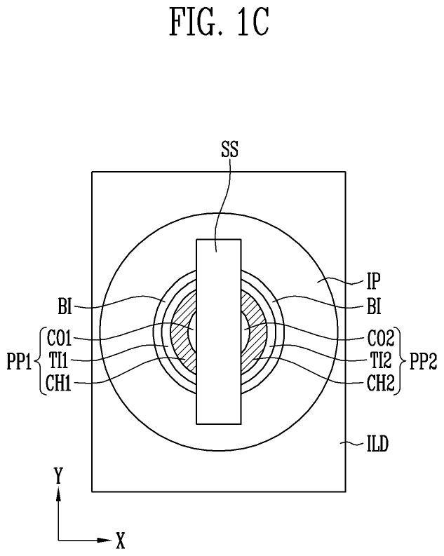

FIGS. 1A, 1B, and 1C are a cross-sectional diagram and plan views for illustrating a semiconductor device according to an embodiment of the present disclosure.

FIG. 1A is a cross-sectional view of a semiconductor device. FIG. 1B is a plan view at a level of a single conductive layer CP. FIG. 1C is a plan view at a level of a single interlayer insulating layer ILD.

Referring to FIGS. 1A, 1B, and 1C, a gate stacked structure GST which is disposed on a substrate SUB may include conductive layers CP and interlayer insulating layers ILD which are stacked alternately with each other. The conductive layers CP may be gate electrodes of a select transistor, a memory cell, and the like. The conductive layers CP may be a select line coupled to a select transistor, a word line coupled to a memory cell, and the like. The conductive layers CP may include a conductive material such as polysilicon, tungsten, metal, or the like. The interlayer insulating layers ILD may be provided to insulate the stacked conductive layers CP from each other. The interlayer insulating layers ILD may include an insulating material such as oxide or nitride. The conductive layers CP may include lateral portions which protrude further than the interlayer insulating layers ILD toward a first plug pattern PP1 or a second plug pattern PP2. Insulating patterns IP may be arranged on sidewalls of the interlayer insulating layers ILD adjacent to the first plug pattern PP1 or the second plug pattern PP2. The insulating pattern IP may include lateral portions which protrude further than the conductive layers CP toward the first plug pattern PP1 or the second plug pattern PP2. In an embodiment, the insulating pattern IP may include lateral portions which protrude further than the conductive layers CP toward the first plug pattern PP1 or the second plug pattern PP2 as shown in FIG. 1A.

The first plug pattern PP1 and the second plug pattern PP2 may pass through the gate stacked structure GST and extend in a first direction Z perpendicular to the substrate SUB. That is, the first plug pattern PP1 and the second plug pattern PP2 may extend in a stacking direction of the gate stacked structure GST. The stacking direction of the gate stacked structure GST may be defined as a direction in which the conductive layers CP and the interlayer insulating layers ILD included in the gate stacked structure GST are stacked alternately with each other. In an embodiment, the conductive layers CP and the interlayer insulating layers ILD may be stacked in a vertical direction (i.e., first direction Z) to the substrate SUB. As such, as shown in FIG. 1A, in an embodiment, the first plug pattern PP1 and the second plug pattern PP2 extend in a vertical direction corresponding to a stacking direction of the gate stacked structure GST.

In an embodiment, a plug pattern may include both a first plug pattern PP1 and a second plug pattern PP2. In an embodiment, the isolation structure 22 may pass through the plug pattern in the vertical direction to separate the plug pattern into the first and second pug patterns PP1 and PP2. The first plug pattern PP1 may include a first tunnel isolation layer TI1, a first channel layer CH1, and a first core insulating layer CO1.

The first core insulating layer CO1 may extend in the first direction Z and include an insulating material such as oxide. An inner wall of the first core insulating layer CO1 may contact an isolation structure SS. The first channel layer CH1 may contact an outer wall of the first core insulating layer CO1 and extend in the first direction Z. The first channel layer CH1 may include a semiconductor material such as silicon or germanium, or a nanostructure such as nanodots, nanotubes, or graphene. The first tunnel isolation layer TI1 may contact an outer wall of the first channel layer CH1 and extend in the first direction Z. Charges may be tunneled into the first tunnel isolation layer TI1 by Fowler-Nordheim (F-N) tunneling. The first tunnel isolation layer TI1 may include an insulating material such as oxide or nitride.

The second plug pattern PP2 may include a second tunnel isolation layer TI2, a second channel layer CH2, and a second core insulating layer CO2.

The second core insulating layer CO2 may extend in the first direction Z and include an insulating material such as oxide. An inner wall of the second core insulating layer CO2 may contact the isolation structure SS. The second channel layer CH2 may contact an outer wall of the second core insulating layer CO2 and extend in the first direction Z. The second channel layer CH2 may include a semiconductor material such as silicon or germanium, or a nanostructure such as nanodots, nanotubes, or graphene. The second tunnel isolation layer TI2 may contact an outer wall of the second channel layer CH2 and extend in the first direction Z. Charges may be tunneled into the second tunnel isolation layer TI2 by F-N tunneling. The second tunnel isolation layer TI2 may include an insulating material such as oxide or nitride.

The isolation structure SS may be disposed between the first plug pattern PP1 and the second plug pattern PP2, may extend in the first direction Z, and may include an insulating material such as oxide. The first plug pattern PP1 and the second plug pattern PP2 may have a symmetrical structure with respect to the isolation structure SS. For example, the first plug pattern PP1 and the second plug pattern PP2 may have a symmetrical structure in a second direction X corresponding to a horizontal direction.

The isolation structure SS may extend in the first direction Z and may separate the first plug pattern PP1 and the second plug pattern PP2 physically and electrically from each other. In addition, the isolation structure SS may extend in a third direction Y which is a horizontal direction perpendicular to the second direction X. For example, the isolation structure SS may extend in the third direction Y and may separate a first data storage layer DS1 and a second data storage layer DS2 physically and electrically from each other. In addition, the isolation structure SS may pass through a blocking insulating layer BI in the third direction Y.

Though not shown, the isolation structure SS may further extend in the third direction Y and pass through the conductive layers CP in the third direction Y.

The blocking insulating layer BI and the data storage layer DS1 or DS2 may be disposed between the conductive layers CP and the first and second plug patterns PP1 and PP2. For example, the first data storage layer DS1 may be disposed in spaces between the insulating patterns IP adjacent to each other in the first direction Z and between the first plug pattern PP1 and the conductive layers CP. The blocking insulating layer BI may be disposed to be in contact with upper and lower surfaces of the first data storage layer DS1 and a sidewall of the first data storage layer DS1 adjacent to the conductive layer CP. In addition, the second data storage layer DS2 may be disposed in spaces between the insulating patterns IP adjacent to each other in the first direction Z and between the second plug pattern PP2 and the conductive layers CP. In an embodiment, as shown in FIG. 1A, the blocking insulating layer BI may be disposed to be in contact with upper and lower surfaces of the first data storage layer DS1 and a sidewall of the first data storage layer DS1 adjacent to the conductive layer CP. In an embodiment, as shown in FIG. 1A, the second data storage layer DS2 may be disposed in spaces between the insulating patterns IP adjacent to each other in the first direction Z and between the second plug pattern PP2 and the conductive layers CP. The blocking insulating layer BI may be disposed to be in contact with upper and lower surfaces of the second data storage layer DS2 and a sidewall of the second data storage layer DS2 adjacent to the conductive layer CP. In addition, the blocking insulating layer BI may extend between the insulating patterns IP and the first tunnel isolation layer TI1. In an embodiment, as shown in FIG. 1A, the blocking insulating layer BI may be disposed to be in contact with upper and lower surfaces of the second data storage layer DS2 and a sidewall of the second data storage layer DS2 adjacent to the conductive layer CP. In an embodiment, as shown in FIG. 1A, the blocking insulating layer BI may extend between the insulating patterns IP and the first tunnel isolation layer TI1. In other words, the blocking insulating layer BI may surround upper and lower surfaces of the insulating patterns IP and extend to an interface between the insulating patterns IP and the first plug pattern PP1 and an interface between the insulating patterns IP and the second plug pattern PP2.

The blocking insulating layer BI may include a high-k dielectric layer. A data storage layer DS (i.e., first and second data storage layers DS1 and DS2) may include a charge trap material, a nitride, a variable resistance material, or a nanostructure, or a combination thereof.

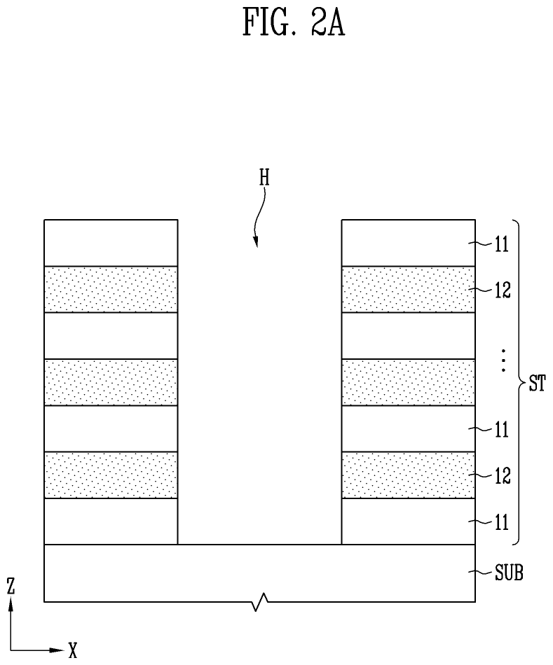

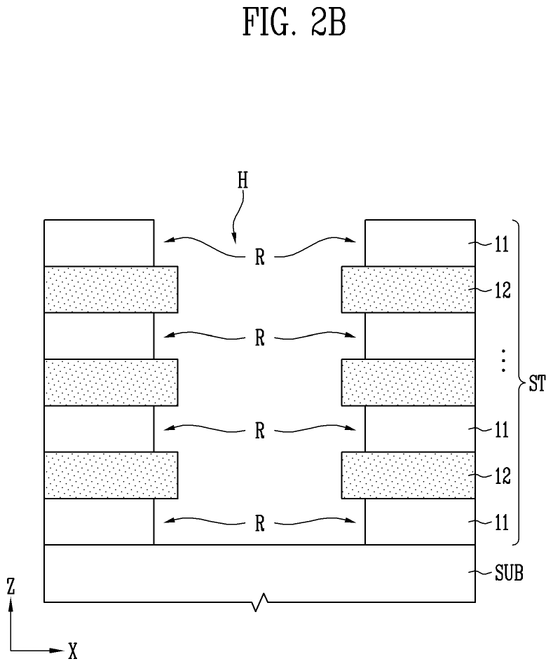

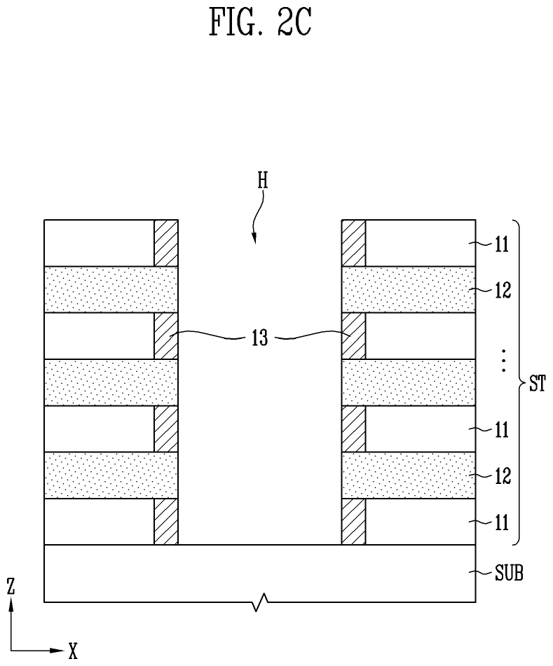

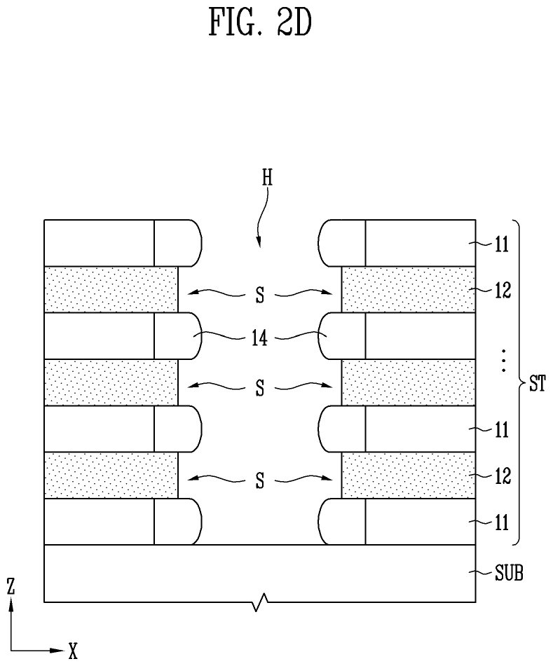

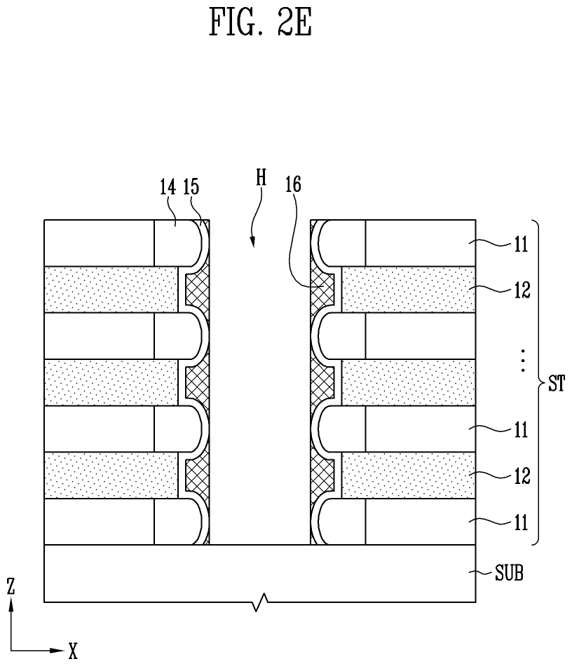

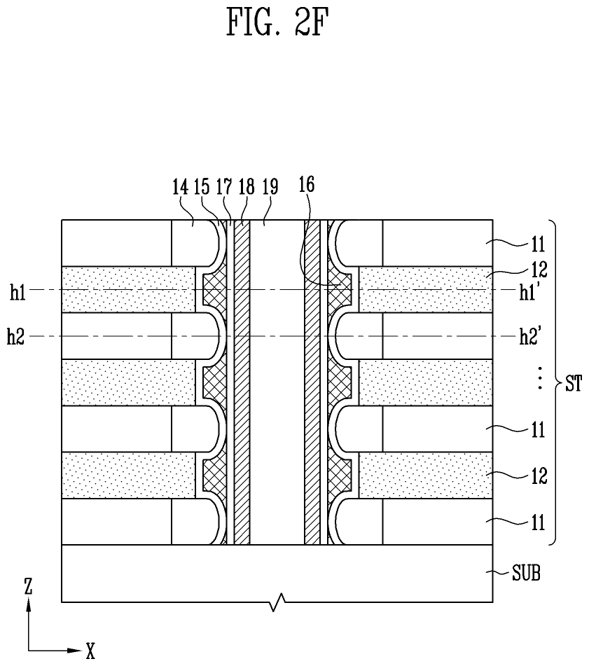

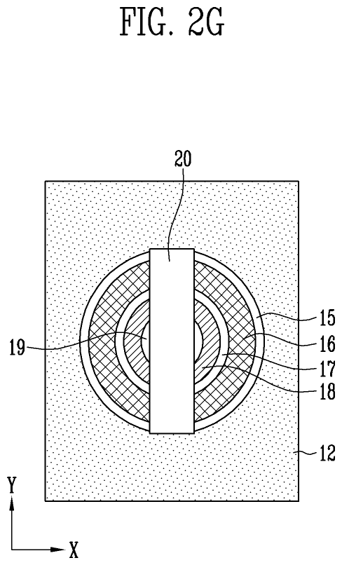

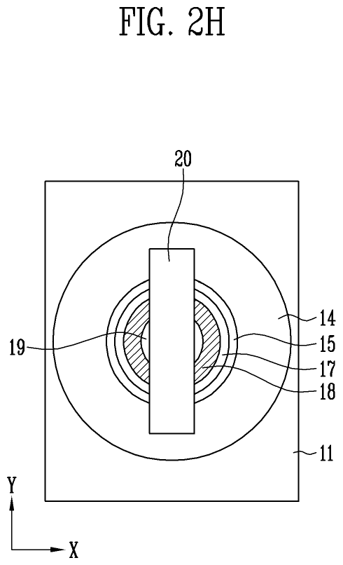

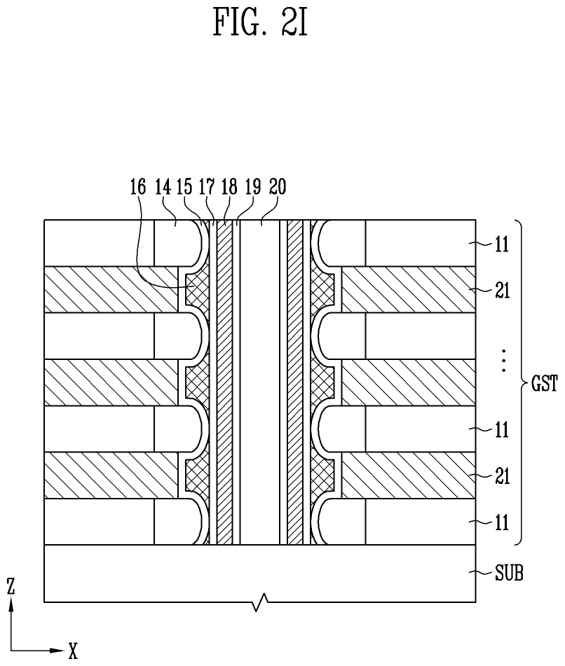

FIGS. 2A, 2B, 2C, 2D, 2E, 2F, 2G, 2H, and 2I are cross-sectional views and plan views for illustrating a method of manufacturing a semiconductor device according to an embodiment of the present disclosure.

Referring to FIG. 2A, a stacked structure ST may be formed on the substrate SUB. The stacked structure ST may include first material layers 11 and second material layers 12 which are staked alternately with each other. The first and second material layers 11 and 12 may be stacked in a direction vertical to the substrate SUB. The first and second material layers 11 and 12 may be formed using a deposition process such as chemical vapor deposition (CVD).

The first material layers 11 may include a material having a high etch selectivity with respect to the second material layers 12. For example, the first material layers 11 may include an insulating material such as oxide and the second material layers 12 may include a sacrificial material such as nitride. In another example, the first material layers 11 may include an insulating material such as oxide and the second material layers 12 may include a conductive material such as polysilicon and tungsten.

Subsequently, a hard mask pattern (not shown) may be formed on the stacked structure ST, and an etch process using the hard mask pattern may be performed to form a hole H which passes through at least a portion of the stacked structure ST. The hole H may be partially extended into the substrate SUB.

Referring to FIG. 2B, recessed regions R may be formed by etching the first material layers 11 exposed through the hole H to a predetermined depth in a horizontal direction. In other words, sidewalls of the first material layers 11 may be etched to the predetermined depth so that the second material layers 12 may protrude further than the first material layers 11 in the horizontal direction. The word “predetermined” as used herein with respect to a parameter, such as a predetermined depth or predetermined thickness, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Referring to FIG. 2C, sacrificial patterns 13 may be formed in the recessed regions R in FIG. 2B. The sacrificial patterns 13 may include a polysilicon layer or a silicon nitride layer. For example, a polysilicon layer or a silicon nitride layer may be formed on a sidewall of the hole H such that the recessed region R of FIG. 2B may be completely buried. An etch-back process may be performed to expose sidewalls of the second material layers 12 so that the polysilicon layer or the silicon nitride layer may remain only in the recessed regions R of FIG. 2B to thereby form the sacrificial patterns 13.

Referring to FIG. 2D, an oxidation process may be performed to selectively oxidize the sacrificial patterns 13 of FIG. 2C, so that insulating patterns 14 may be formed. The insulating patterns 14 may have protrusions which protrude in a direction of the hole H. As a result, spaces S may be formed between the protrusions of the insulating patterns 14 adjacent to each other in the first direction Z. As a result, an irregular portion may be formed on the sidewall of the hole H.

Referring to FIG. 2E, a blocking insulating layer 15 may be formed on the sidewall of the hole H. The blocking insulating layer 15 may be formed on surfaces of the protrusions of the insulating patterns 14 and the sidewalls of the second material layers 12. The blocking insulating layer 15 may include a high-k dielectric layer. For example, the blocking insulating layer 15 may include a high-k material such as aluminum oxide (Al₂O₃), hafnium oxide (HfOx), hafnium silicon oxide (HfSiOx), or the like.

Subsequently, a data storage layer 16 may be formed in the spaces S in FIG. 2D. For example, after the data storage layer 16 is formed on a sidewall of the blocking insulating layer 15, an etchback process may be performed thereon such that the data storage layers 16 may remain only in the spaces S in FIG. 2D. As a result, the blocking insulating layers 15 which contact the sidewalls of the insulating patterns 14 may be exposed through the hole H. The data storage layer 16 may include a charge trap material, a nitride, a variable resistance material, or a nanostructure, or a combination thereof.

Referring to FIG. 2F, a tunnel isolation layer 17 may be formed on a sidewall of the data storage layer 16 and a sidewall of the blocking insulating layer 15 exposed through the hole H of FIG. 2E. The tunnel isolation layer 17 may be a layer where charges are tunneled by Fowler-Nordheim (F-N) tunneling, and may include an insulating material such as oxide or nitride.

A channel layer 18 may then be formed on a sidewall of the tunnel isolation layer 17. The channel layer 18 may include a semiconductor material. According to an embodiment, the channel layer 18 may include a semiconductor material, such as silicon or germanium, or a nanostructure, such as nanodots, nanotubes, or graphene.

A core insulating layer 19 may be formed to fill a central area of the hole H. The core insulating layer 19 may include an insulating material such as an oxide layer.

FIG. 2G is a cross-sectional view at a first level h1-h1′ of FIG. 2F. FIG. 2H is a cross-sectional view at a second level h2-h2′ of FIG. 2F. Referring to FIGS. 2G and 2H, an etch process may be performed to form a trench having a line shape which passes through the core insulating layer 19, the channel layer 18, the tunnel isolation layer 17, the data storage layer 16, and the blocking insulating layer 15, which are formed in the hole, in the first direction Z, and an isolation structure 20 may be formed by filling the trench with an insulating material. The isolation structure 20 may extend in the third direction Y. According to an embodiment, the isolation structure 20 may extend in the third direction Y to pass through the core insulating layer 19, the channel layer 18, the tunnel isolation layer 17, the data storage layer 16, the blocking insulating layer 15, the first material layer 11, and the second material layer 12, and may divide these layers in two symmetrical parts in the second direction X.

Referring to FIG. 2I, an etch process may be performed to expose a sidewall of the stacked structure ST of FIG. 2F and the exposed portions of the second material layers 12 of FIG. 2F may be removed. Subsequently, third material layers 21 may be formed in spaces from which the exposed portions of the second material layers are removed. The third material layers 21 may include a conductive material such as polysilicon, tungsten, metal, or the like. The first material layers 11 and the second material layers 21 may be defined as the gate stacked structure GST.

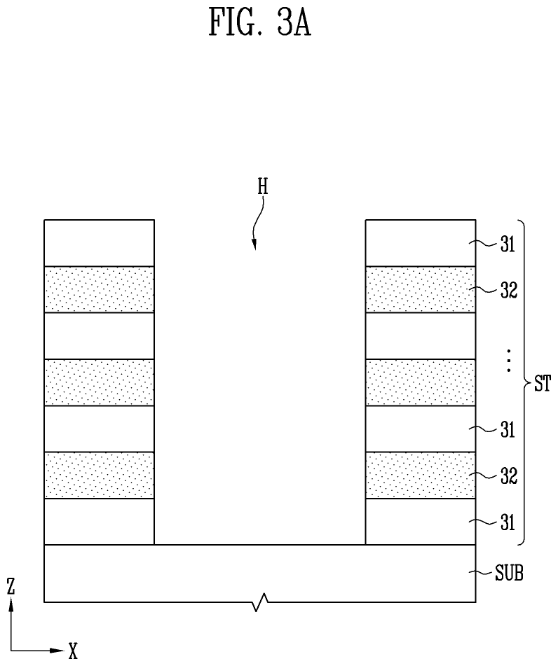

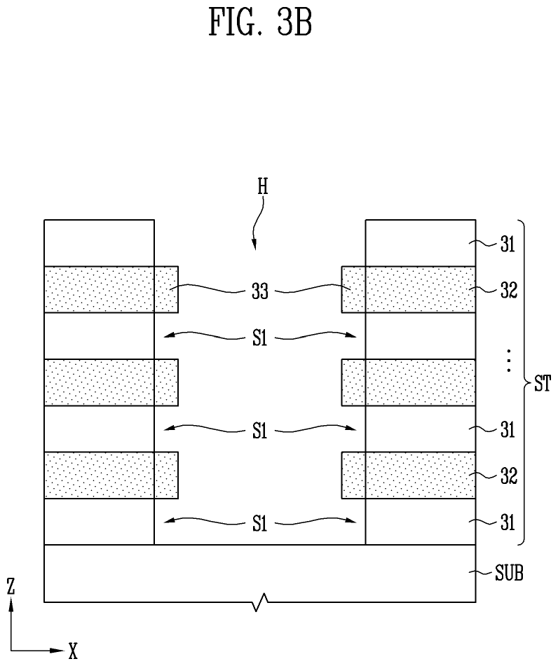

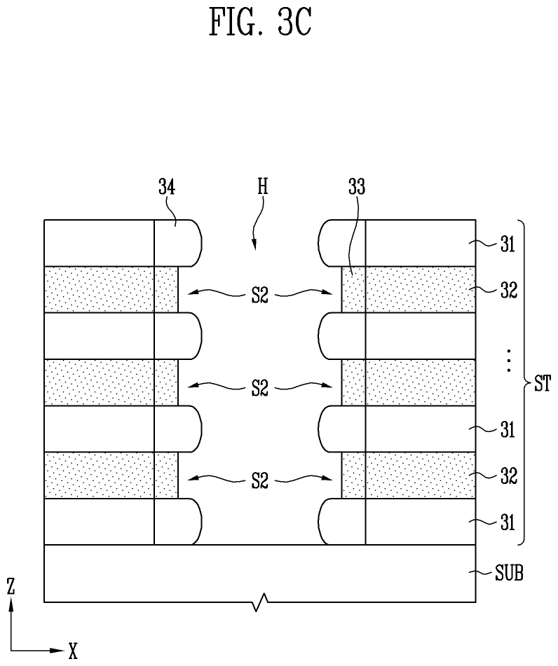

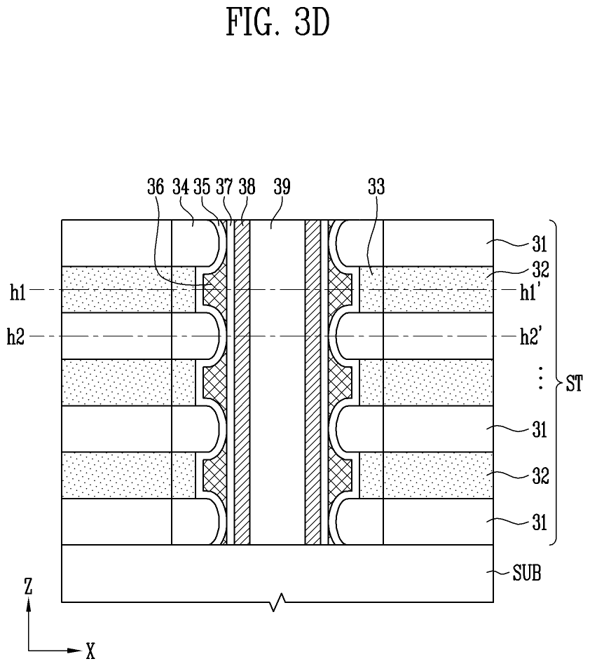

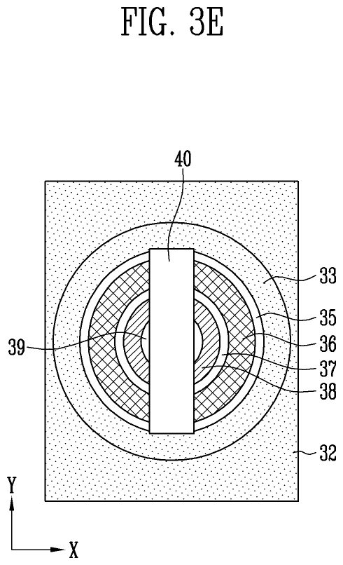

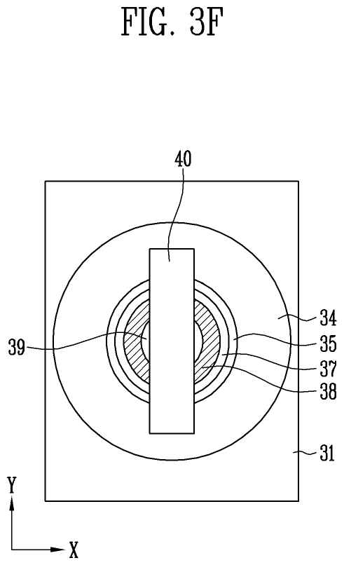

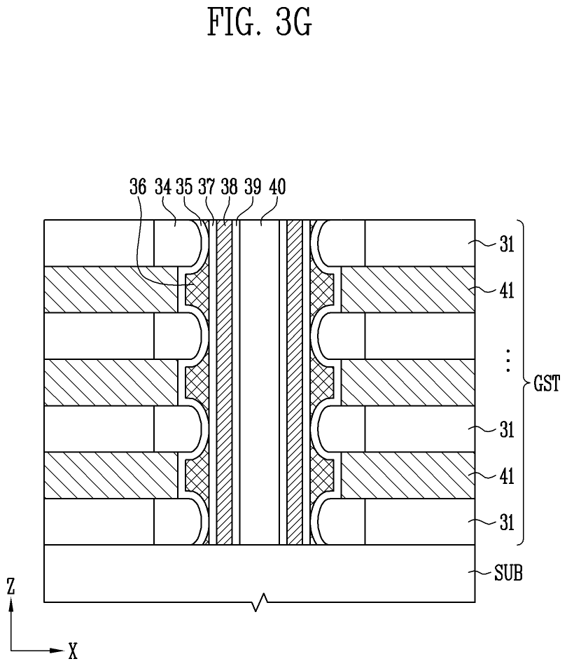

FIGS. 3A, 3B, 3C, 3D, 3E, 3F, and 3G are cross-sectional views and plan views for illustrating a method of manufacturing a semiconductor device according to an embodiment of the present disclosure.

Referring to FIG. 3A, the stacked structure ST may be formed on the substrate SUB and later a gate stacked structure may be formed as shown in FIG. 3G. The stacked structure ST may include first material layers 31 and second material layers 32 which are staked alternately with each other. The first and second material layers 31 and 32 may be stacked in a direction vertical to the substrate SUB. The first and second material layers 31 and 32 may be formed using a deposition process such as chemical vapor deposition (CVD).

The first material layers 31 may include a material having a high etch selectivity with respect to the second material layers 32. For example, the first material layers 31 may include an insulating material such as oxide and the second material layers 32 may include a sacrificial material such as nitride. In another example, the first material layers 31 may include an insulating material such as oxide and the second material layers 32 may include a conductive material such as polysilicon and tungsten.

Subsequently, a hard mask pattern (not shown) may be formed on the stacked structure ST, and an etch process using the hard mask pattern may be performed to form the hole H which passes through at least a portion of the stacked structure ST. The hole H may be partially extended into the substrate SUB.

Referring to FIG. 3B, protruding patterns 33 may be formed on sidewalls of the second material layers exposed through the hole H. For example, protruding patterns 33 may be formed on sidewalls of the second material layers 32 by performing a selective deposition process. As a result, first spaces S1 may be formed between the protruding patterns 33 adjacent to each other in the first direction Z. The protruding patterns 33 may include the same material as the second material layers 32.

Referring to FIG. 3C, insulating patterns 34 may be formed in the first spaces S1 of FIG. 3B. For example, a polysilicon layer or a silicon nitride layer may be formed on a sidewall of the hole H to completely fill the first spaces S1 of FIG. 3B. Subsequently, an etchback process may be performed to expose sidewalls of the protruding patterns 33 such that the polysilicon layer or the silicon nitride layer may remain only in the first spaces S1 of FIG. 3B, thereby forming sacrificial patterns. Subsequently, the sacrificial patterns may be selectively oxidized through an oxidation process to form the insulating patterns 34. The insulating patterns 34 may have protrusions which protrude in a direction towards the hole H. As a result, second spaces S2 may be formed between the protrusions of the insulating patterns 34 which are adjacent to each other in the first direction Z. As a result, an irregular portion may be formed on the sidewall of the hole H.

Referring to FIG. 3D, a blocking insulating layer 35 may be formed on the sidewall of the hole H in FIG. 3C. The blocking insulating layer 35 may be formed on surfaces of the protrusions of the insulating patterns 34 and sidewalls of the protruding patterns 33. The blocking insulating layer 35 may include a high-k dielectric layer. For example, the blocking insulating layer 35 may include a high-k material such as aluminum oxide (Al₂O₃), hafnium oxide (HfOx), hafnium silicon oxide (HfSiOx), or the like.

Subsequently, a data storage layer 36 may be formed in the second spaces S2 of FIG. 3C. For example, after the data storage layer 36 is formed on the sidewall of the blocking insulating layer 35, an etchback process may be performed, so that the data storage layers 36 may remain only in the second spaces S2 in FIG. 3C. As a result, the blocking insulating layers 35 which contact the sidewalls of the insulating patterns 34 may be exposed through the hole H of FIG. 3. The data storage layer 36 may include a charge trap material, a nitride, a variable resistance material, or a nanostructure, or a combination thereof.

Subsequently, a tunnel isolation layer 37 may be formed on the sidewall of the data storage layer 36 and the sidewall of the blocking insulating layer 35 which are exposed through the hole H. The tunnel isolation layer 37 may be a layer where charges are tunneled by Fowler-Nordheim (F-N) tunneling, and may include an insulating material such as oxide or nitride.

A channel layer 38 may be formed on a sidewall of the tunnel isolation layer 37. The channel layer 38 may include a semiconductor material. According to an embodiment, the channel layer 38 may include a semiconductor material, such as silicon or germanium, or a nanostructure, such as nanodots, nanotubes, or graphene.

A core insulating layer 39 may then be formed to fill a central area of the hole. The core insulating layer 39 may include an insulating material such as an oxide layer.

FIG. 3E is a cross-sectional view at the first level h1-h1′ of FIG. 3D. FIG. 3F is a cross-sectional view at the second level h2-h2′ of FIG. 3D. Referring to FIGS. 3E and 3F, an etch process may be performed to form a trench having a line shape which passes through the core insulating layer 39, the channel layer 38, the tunnel isolation layer 37, the data storage layer 36, and the blocking insulating layer 35, which are formed in the hole, in the first direction Z, and an isolation structure 40 may be formed by filling the trench with an insulating material. The isolation structure 40 may extend in the third direction Y. According to an embodiment, the isolation structure 40 may extend in the third direction Y to pass through the core insulating layer 39, the channel layer 38, the tunnel isolation layer 37, the data storage layer 36, the blocking insulating layer 35, the first material layer 31, and the second material layer 32, and may divide these layers in two symmetrical parts in the second direction X.

Referring to FIG. 3G, an etch process may be performed to expose the sidewall of the stacked structure ST of FIG. 3D, the exposed portions of the second material layers 32 of FIG. 3D may be removed, and the exposed protruding patterns 33 of FIG. 3D may be removed. Subsequently, third material layers 41 may be formed in spaces from which the exposed portions of the second material layers and the protruding patterns are removed. The third material layers 41 may include a conductive material such as polysilicon, tungsten, metal, or the like. The first material layers 31 and the third material layers 41 may be defined as the gate stacked structure GST.

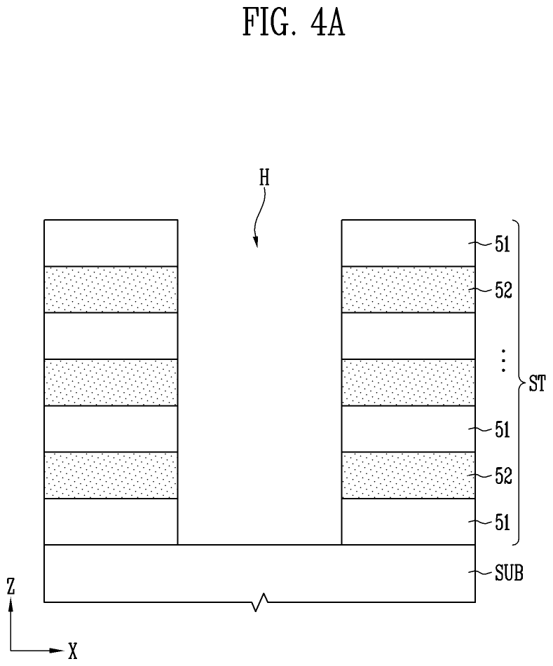

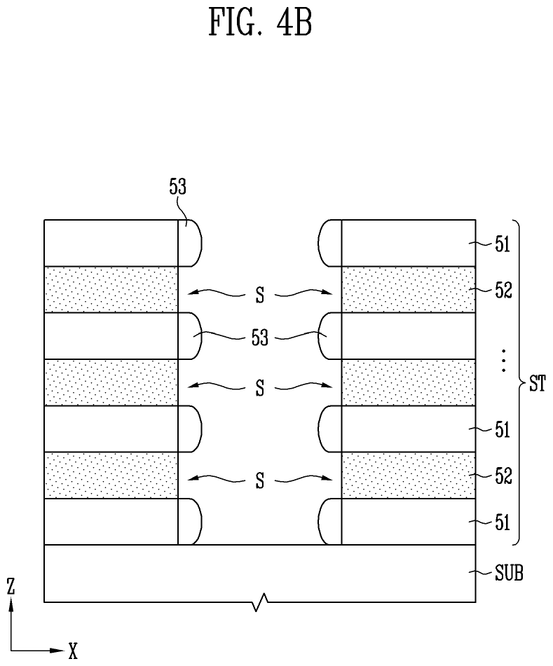

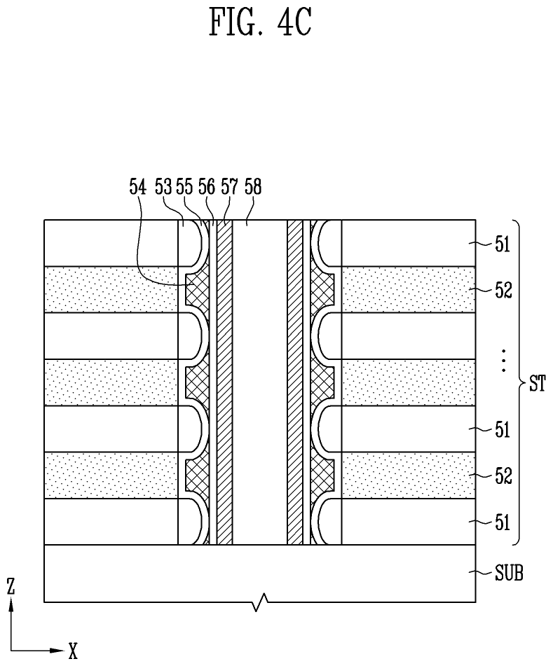

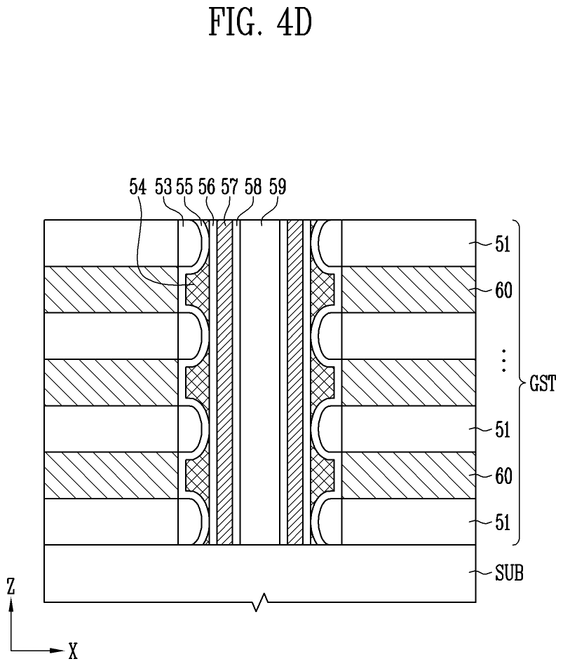

FIGS. 4A, 4B, 4C, and 4D are cross-sectional views for illustrating a method of manufacturing a semiconductor device according to an embodiment of the present disclosure.

Referring to FIG. 4A, the stacked structure ST may be formed on the substrate SUB, and later a gate stacked structure may be formed on the substrate as shown in FIG. 4D. The stacked structure ST may include first material layers 51 and second material layers 52 which are staked alternately with each other. The first and second material layers 51 and 52 may be stacked in a direction vertical to the substrate SUB. The first and second material layers 51 and 52 may be formed using a deposition process such as chemical vapor deposition (CVD).

The first material layers 51 may include a material having a high etch selectivity with respect to the second material layers 52. For example, the first material layers 51 may include an insulating material such as oxide and the second material layers 52 may include a sacrificial material such as nitride. In another example, the first material layers 51 may include an insulating material such as oxide and the second material layers 52 may include a conductive material such as polysilicon and tungsten.

Subsequently, a hard mask pattern (not shown) may be formed on the stacked structure ST, and an etch process using the hard mask pattern may be performed to form the hole H which passes through at least a portion of the stacked structure ST. The hole H may be partially extended into the substrate SUB.

Referring to FIG. 4B, insulating patterns 53 may be formed on sidewalls of the first material layers 51 which are exposed through the hole H. The insulating pattern 53 may be formed using a selective deposition process and include oxide. As a result, the spaces S may be formed between the insulating patterns 53 adjacent to each other in the first direction Z. As a result, an irregular portion may be formed on the sidewall of the hole H.

Referring to FIG. 4C, a blocking insulating layer 54 may be formed on the sidewall of the hole H of FIG. 4B. The blocking insulating layer 54 may be formed on the exposed surface of the insulating pattern 53 and the sidewalls of the second material layers 52. The blocking insulating layer 54 may include a high-k dielectric layer. For example, the blocking insulating layer 54 may include a high-k material such as aluminum oxide (Al₂O₃), hafnium oxide (HfOx), hafnium silicon oxide (HfSiOx), or the like.

Subsequently, a data storage layer 55 may be formed in the spaces S in FIG. 4B. For example, after the data storage layer 55 is formed on the sidewall of the blocking insulating layer 54, an etchback process may be performed such that the data storage layers 55 may remain only in the spaces S in FIG. 4B. As a result, the blocking insulating layers 54 which contact the sidewalls of the insulating patterns 53 may be exposed through the hole H of FIG. 4B. The data storage layer 55 may include a charge trap material, a nitride, a variable resistance material, or a nanostructure, or a combination thereof.

Subsequently, a tunnel isolation layer 56 may be formed on the sidewall of the data storage layer 55 and the sidewall of the blocking insulating layer 54 which are exposed through the hole H in FIG. 4B. The tunnel isolation layer 56 may be a layer where charges are tunneled by Fowler-Nordheim (F-N) tunneling, and may include an insulating material, such as oxide or nitride.

A channel layer 57 may be formed on a sidewall of the tunnel isolation layer 56. The channel layer 57 may include a semiconductor material. According to an embodiment, the channel layer 57 may include a semiconductor material, such as silicon or germanium, or a nanostructure, such as nanodots, nanotubes, or graphene.

A core insulating layer 58 may then be formed to fill a central area of the hole H. The core insulating layer 58 may include an insulating material such as an oxide layer.

Referring to FIG. 4D, an isolation structure 59 may be formed. The isolation structure 59 may pass through the core insulating layer 58, the channel layer 57, the tunnel isolation layer 56, the data storage layer 55, and the blocking insulating layer 54 in the first direction Z. An etch process may be performed as described above with reference to FIGS. 2G and 2H or 3E and 3F to form a trench having a line shape which passes through the core insulating layer 58, the channel layer 57, the tunnel isolation layer 56, the data storage layer 55, and the blocking insulating layer 54, which are formed in the hole, in the first direction Z, and the hole may be filled with an insulating material. In this manner, the isolation structure 59 may be formed.

Subsequently, an etch process may be performed to expose a sidewall of the stacked structure ST of FIG. 4C and the exposed portions of the second material layers 52 of FIG. 4C may be removed. Subsequently, third material layers 60 may be formed in spaces from which the exposed portions of the second material layers are removed. The third material layers 60 may include a conductive material such as polysilicon, tungsten, metal, or the like. The first material layers 51 and the third material layers 60 may be defined as the gate stacked structure GST.

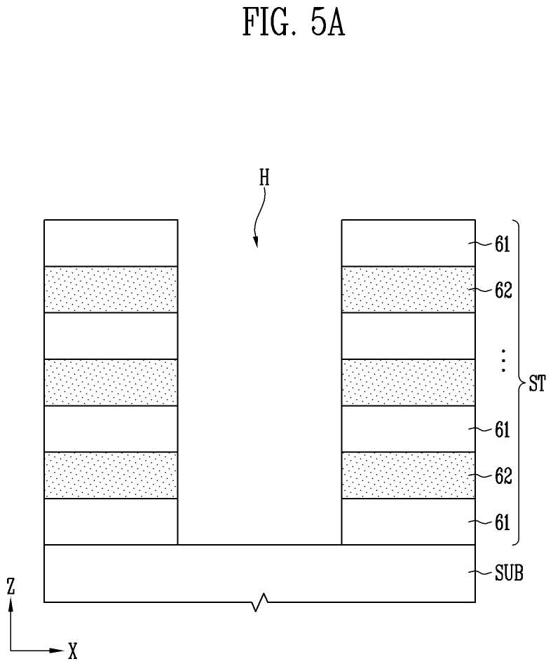

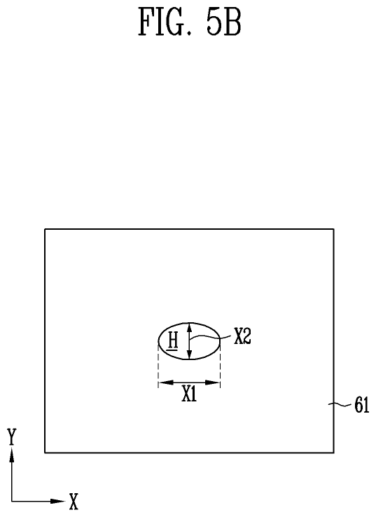

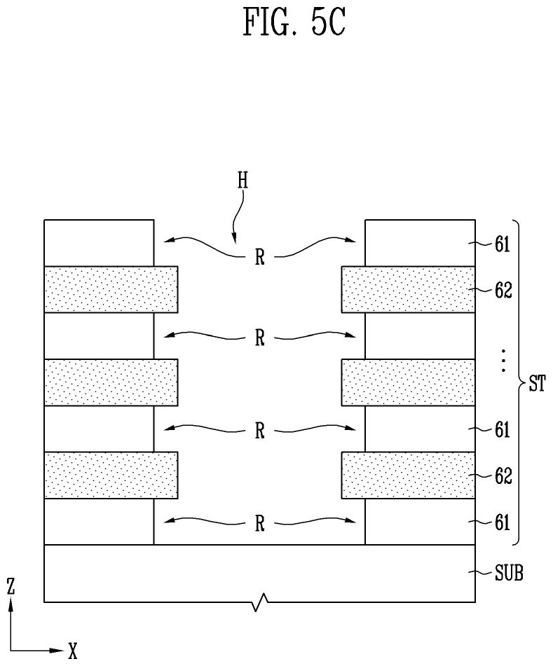

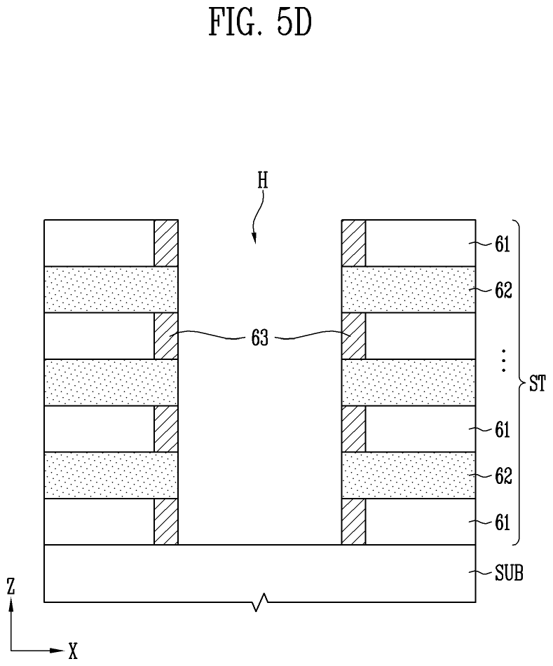

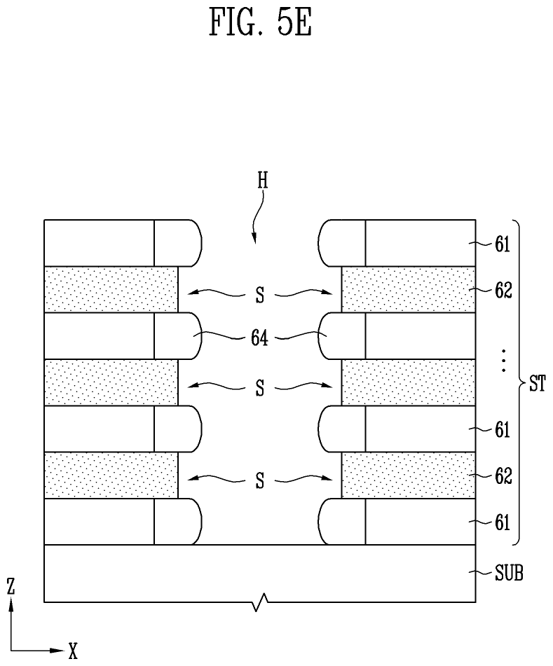

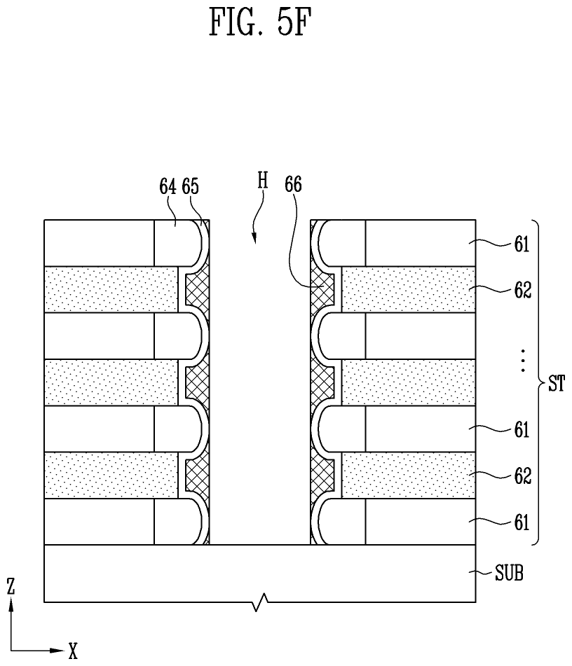

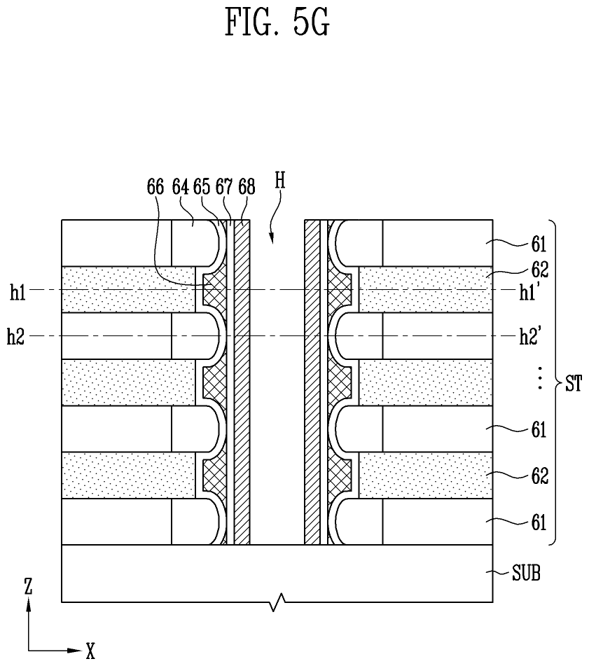

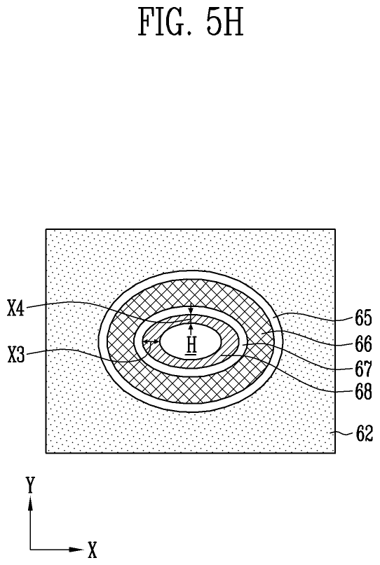

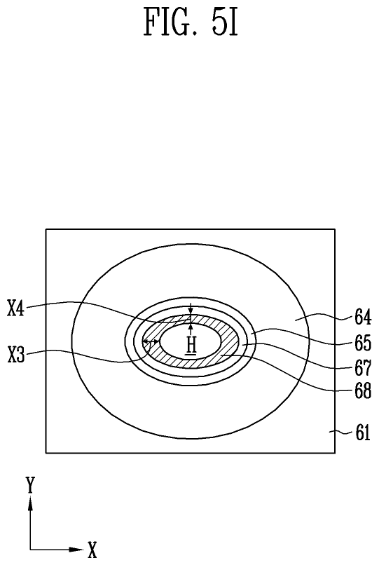

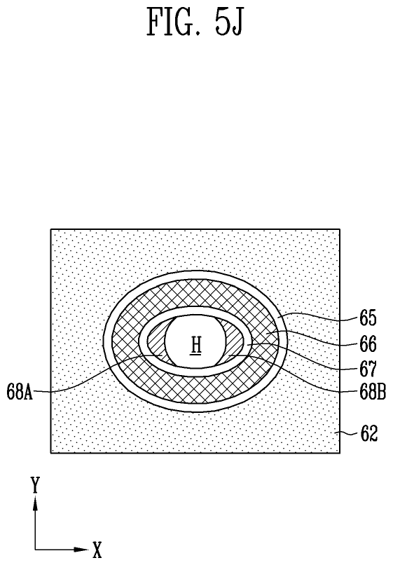

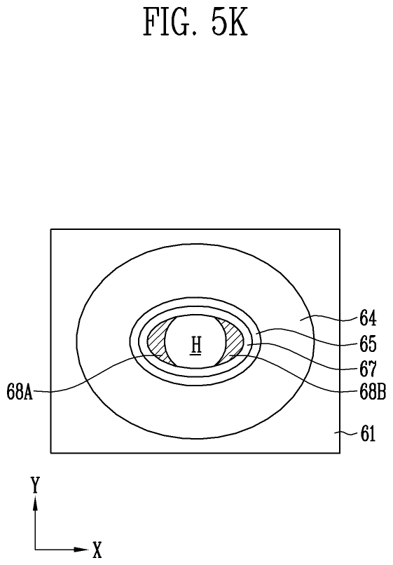

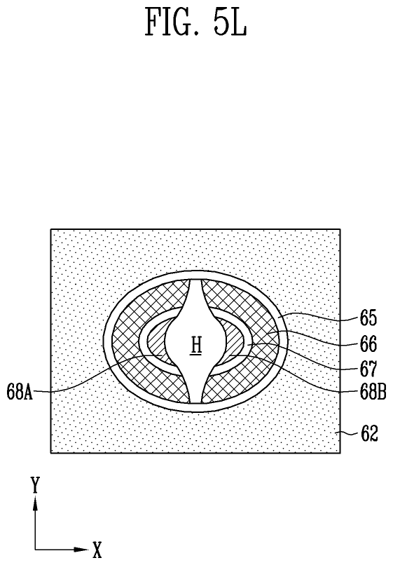

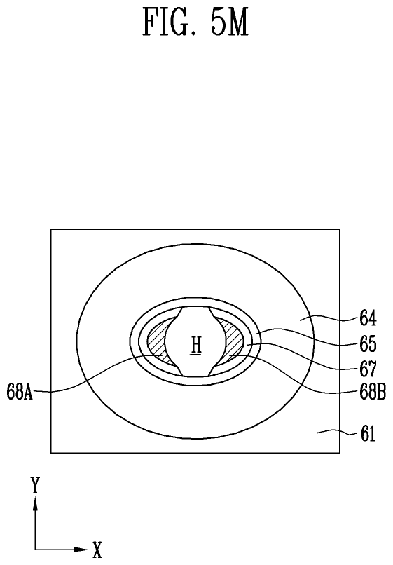

FIGS. 5A, 5B, 5C, 5D, 5E, 5F, 5G, 5H, 5I, 5J, 5K, 5L, and 5M are cross-sectional views and plan views for illustrating a method of manufacturing a semiconductor device according to an embodiment of the present disclosure.

Referring to FIGS. 5A and 5B, the stacked structure ST may be formed on the substrate SUB. The stacked structure ST may include first material layers 61 and second material layers 62 that are staked alternately with each other. The first and second material layers 61 and 62 may be stacked in a perpendicular direction to the substrate SUB. The first and second material layers 61 and 62 may be formed using a deposition process such as chemical vapor deposition (CVD).

The first material layers 61 may include a material having a high etch selectivity with respect to the second material layers 62. For example, the first material layers 61 may include an insulating material such as oxide and the second material layers 62 may include a sacrificial material such as nitride. In another example, the first material layers 61 may include an insulating material such as oxide and the second material layers 62 may include a conductive material such as polysilicon and tungsten.

Subsequently, a hard mask pattern (not shown) may be formed on the stacked structure ST, and an etch process using the hard mask pattern may be performed to form the hole H which passes through at least a portion of the stacked structure ST. The hole H may be partially extended into the substrate SUB.

The hole H may have an elliptical shape. For example, a diameter X1 of the hole H in the second direction X may be greater than a diameter X2 of the hole H in the third direction Y.

Referring to FIG. 5C, the recessed region R may be formed by etching first material layers 61, which are exposed through the hole H, to a predetermined depth in a horizontal direction. In other words, sidewalls of the first material layers 61 may be etched to a predetermined depth so that the second material layers 62 may protrude more than the first material layers 61.

Referring to FIG. 5D, a sacrificial pattern 63 may be formed in the recessed region R in FIG. 5C. The sacrificial pattern 63 may include a polysilicon layer or a silicon nitride layer. For example, a polysilicon layer or a silicon nitride layer may be formed along a sidewall of the hole H such that the recessed region R of FIG. 5C may be completely buried. An etch-back process may be performed to expose a sidewall of the second material layer 62 so that the polysilicon layer or the silicon nitride layer may remain only in the recessed region R of FIG. 2B to form the sacrificial pattern 63.

Referring to FIG. 5E, an oxidation process may be performed to selectively oxidize the sacrificial pattern 63 of FIG. 5D, so that an insulating pattern 64 may be formed. The insulating pattern 64 may have a protrusion which protrudes in a direction of the hole H. Thus, the spaces S may be formed between protrusions of the insulating patterns 64 adjacent to each other in the first direction Z. As a result, an irregular portion may be formed on the sidewall of the hole H.

Referring to FIG. 5F, a blocking insulating layer 65 may be formed on the sidewall of the hole H. The blocking insulating layer 65 may be formed on surfaces of the protrusions of the insulating patterns 64 and the sidewalls of the second material layers 62. The blocking insulating layer 65 may include a high dielectric layer. For example, the blocking insulating layer 65 may include a high-k material such as aluminum oxide (Al₂O₃), hafnium oxide (HfOx), hafnium silicon oxide (HfSiOx), or the like.

Subsequently, a data storage layer 66 may be formed in the spaces S in FIG. 5E. For example, after the data storage layers 66 is formed on the sidewalls of the blocking insulating layers 65, an etchback process may be performed such that the data storage layers 66 may remain only in the spaces S in FIG. 5E. As a result, the blocking insulating layers 65 contacting the sidewalls of the insulating patterns 64 may be exposed through the hole H. The data storage layer 66 may include a charge trap material, a nitride, a variable resistance material, or a nanostructure, or a combination thereof.

Referring to FIG. 5G, a tunnel isolation layer 67 may be formed on the sidewall of the data storage layer 66 and the blocking insulating layer 65 which are exposed through the hole H. The tunnel isolation layer 67 may be a layer where charges are tunneled by Fowler-Nordheim (F-N) tunneling, and may include an insulating material, such as oxide or nitride.

A channel layer 68 may be formed on a sidewall of the tunnel isolation layer 67. The channel layer 68 may include a semiconductor material. According to an embodiment, the channel layer 68 may include a semiconductor material, such as silicon or germanium, or a nanostructure, such as nanodots, nanotubes, or graphene.

FIG. 5H is a cross-sectional view at the first level h1-h1′ of FIG. 5G. FIG. 5I is a cross-sectional view at the second level h2-h2′ of FIG. 5G. Referring to FIGS. 5H and 5I, since the hole H has an elliptical shape, a thickness of a cross section X3 of the channel layer 68 in the second direction X may be greater than a thickness of a cross section X4 of the channel layer 68 in the third direction Y.

Referring to FIGS. 5J and 5K, the channel layer 68 of FIGS. 5H and 5I which is exposed through the hole H may be etched to a predetermined thickness to form a first channel layer 68A and a second channel layer 68B which are divided in the second direction X. The first channel layer 68A and the second channel layer 68B each may have a crescent shape so that the first channel layer 68A and the second channel layer 68B may be symmetrical with respect to each other. In addition, a portion of the tunnel isolation layer 67 opposing the first and second channel layers 68A and 68B in the third direction Y may be etched.

Referring to FIGS. 5L and 5M, the exposed tunnel isolation layer 67 may be exposed and divided in two parts in the second direction X. The data storage layer 66 may be exposed. Subsequently, the exposed data storage layer 66 may be etched and divided in two parts in the second direction X.

Subsequently, an isolation structure may be formed by filling the hole H.

An etch process may be performed to expose a sidewall of the stacked structure ST of FIG. 5G as described above with reference to FIG. 4D, and the exposed portions of the second material layers 62 of FIG. 5G may be removed. Subsequently, third material layers may be formed in spaces from which the exposed portions of the second material layers are removed. The third material layers may include a conductive material such as polysilicon, tungsten, metal, or the like.

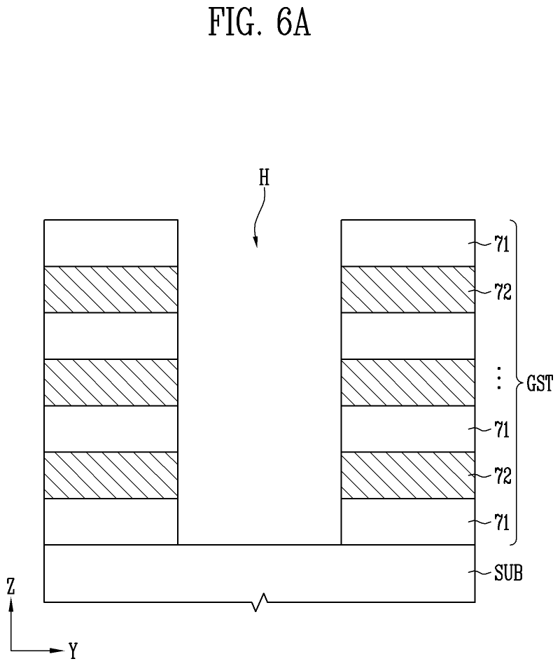

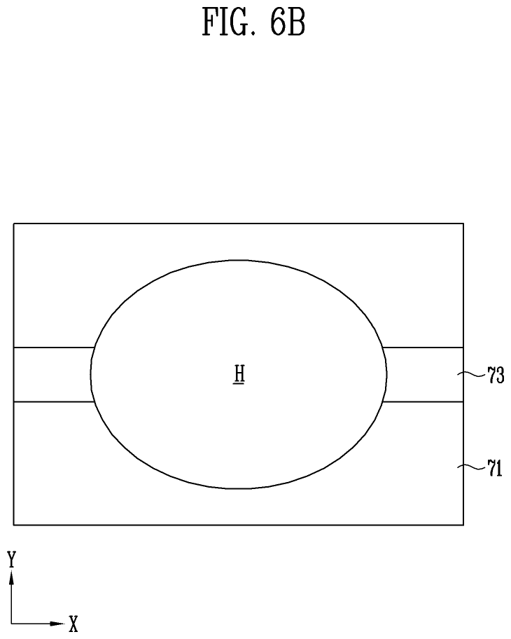

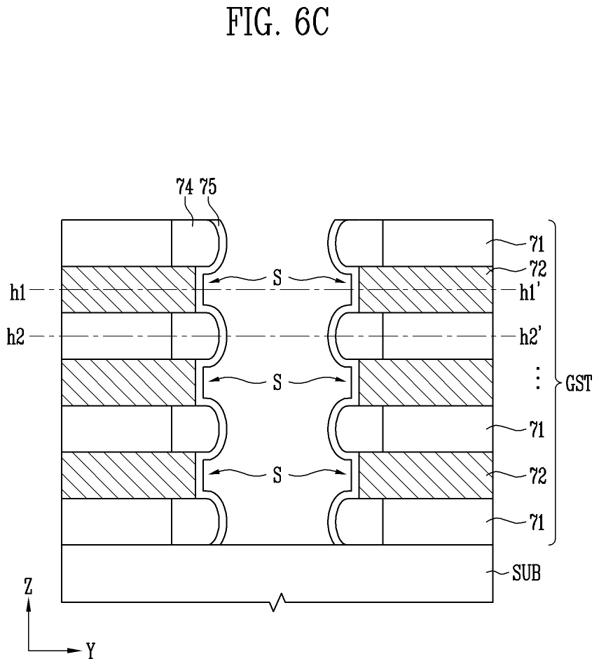

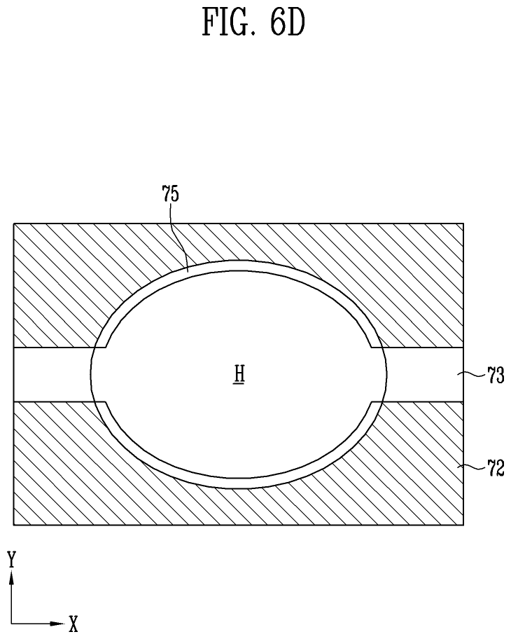

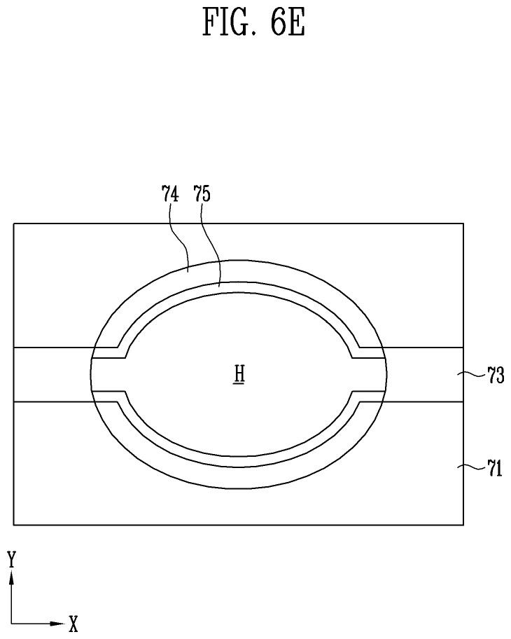

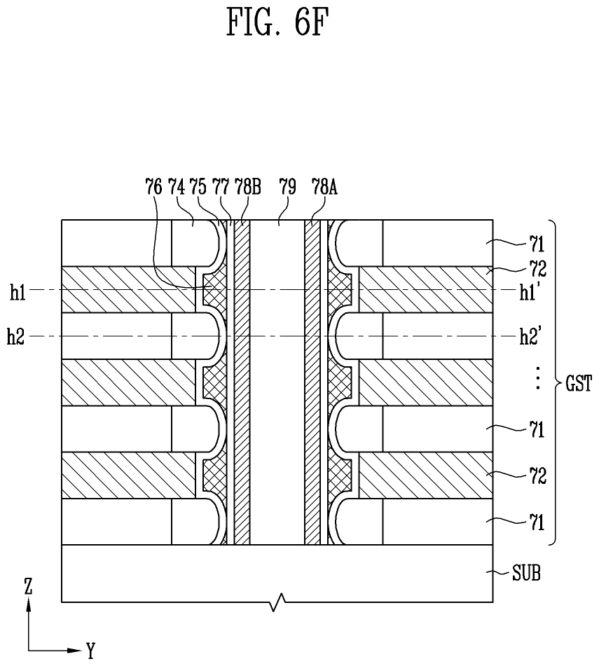

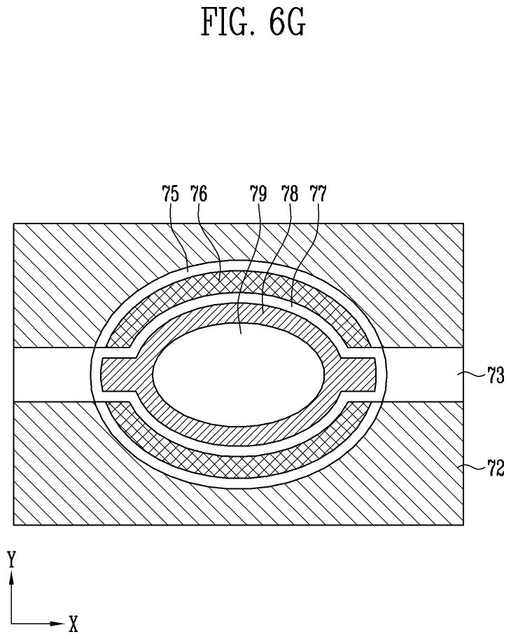

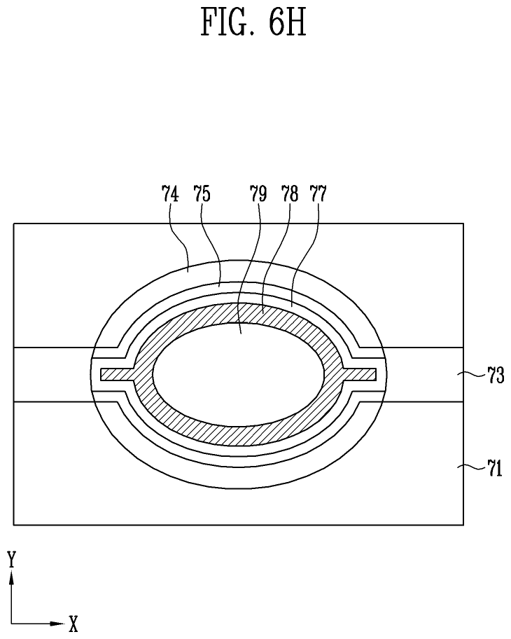

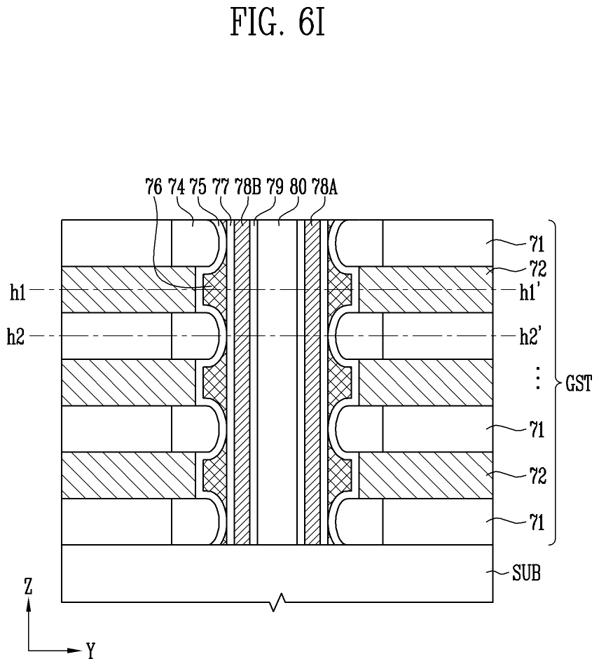

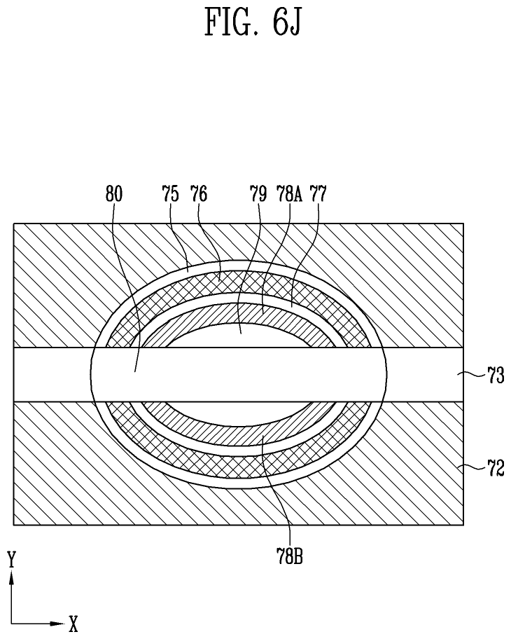

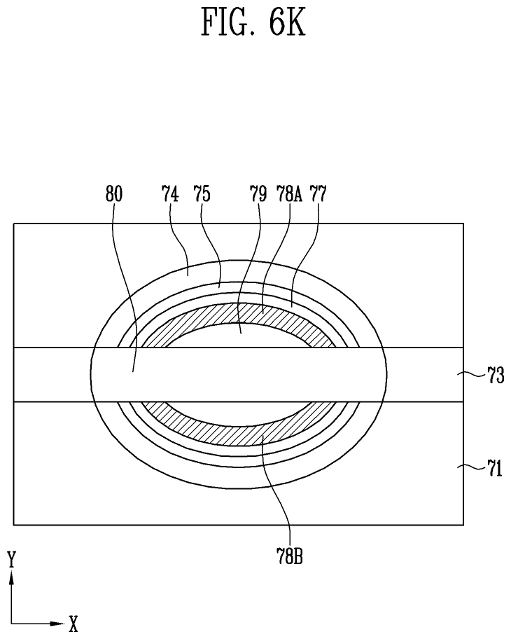

FIGS. 6A, 6B, 6C, 6D, 6E, 6F, 6G, 6H, 6I, 6J, and 6K are cross-sectional views and plan views for illustrating a method of manufacturing a semiconductor device according to an embodiment of the present disclosure.

Referring to FIGS. 6A and 6B, the stacked structure ST may be formed on the substrate SUB and later in FIG. 6I the gate stacked structure GST may be formed. The stacked structure ST may include first material layers 71 and second material layers 72 which are staked alternately with each other. The first and second material layers 71 and 72 may be stacked in a perpendicular direction to the substrate SUB. The first and second material layers 71 and 72 may be formed using a deposition process such as chemical vapor deposition (CVD).

The first material layers 71 may include a material having a high etch selectivity with respect to the second material layers 72. For example, the first material layers 71 may include an insulating material such as oxide and the second material layers 72 may include a conductive material such as polysilicon and tungsten.

Subsequently, a first isolation structure 73 may pass through the stacked structure ST in the first direction Z and extend in the second direction X. For example, a trench having a line shape which passes through the stacked structure ST in the first direction Z and extends in the second direction X may be formed by performing an etch process, and the trench may be filled with an insulating material, thereby forming the first isolation structure 73.

Subsequently, a hard mask (not shown) may be formed on the stacked structure ST and the first isolation structure 73, and an etch process using the hard mask pattern may be performed to thereby form the hole H through the first isolation structure 73. The hole H may be partially extended into the substrate SUB. The hole H may also pass through a portion of the stacked structure ST which is adjacent to the first isolation structure 73.

The hole H may have an elliptical shape. For example, a diameter of the hole H in the second direction X may be greater than a diameter of the hole H in the third direction Y.

FIG. 6D is a cross-sectional view at the first level h1-h1′ of FIG. 6C. FIG. 6E is a cross-sectional view at the second level h2-h2′ of FIG. 6C. Referring to FIGS. 6C, 6D, and 6E, the insulating patterns 74 may be formed on sidewalls of the first material layers 71 which are exposed through the hole H. The insulating pattern 74 may be formed using a selective deposition process and include oxide. As a result, the spaces S may be formed between the insulating patterns 74 adjacent to each other in the first direction Z. As a result, an irregular portion may be formed on the sidewall of the hole H.

The insulating pattern 74 may not be formed at both sides of the hole H in the second direction X which meet the first isolation structure 73. As a result, the insulating patterns 74 may be formed in a C shape such that the insulating patterns 74 may face each other on the basis of the second direction X.

Subsequently, a blocking insulating layer 75 may be formed along surfaces of the second material layers 72 and surfaces of the insulating patterns 74 which are exposed through the hole H The blocking insulating layer 75 may include a high dielectric layer. For example, the blocking insulating layer 75 may include a high-k material such as aluminum oxide (Al₂O₃), hafnium oxide (HfOx), hafnium silicon oxide (HfSiOx), or the like.

FIG. 6G is a cross-sectional view at the first level h1-h1′ of FIG. 6F. FIG. 6H is a cross-sectional view at the second level h2-h2′ of FIG. 6F. Referring to FIGS. 6F, 6G, and 6H, a data storage layer 76 may be formed in the spaces S in FIG. 6C. For example, after the data storage layer 76 is formed on the sidewall of the blocking insulating layer 75, an etchback process may be performed such that the data storage layers 76 may remain only in the spaces S in FIG. 6C. As a result, the blocking insulating layers 75 which contact the sidewalls of the insulating patterns 74 may be exposed through the hole H of FIGS. 6D and 6E. The data storage layer 76 may include a charge trap material, a nitride, a variable resistance material, or a nanostructure, or a combination thereof.

Thereafter, a tunnel isolation layer 77 may be formed on the entire sidewall of the hole H of FIGS. 6D and 6E. For example, the tunnel isolation layer 77 may be formed on the sidewall of the data storage layer 76, the sidewall of the blocking insulating layer 75, and the sidewall of the first isolation structure 73 which are exposed through the hole H of FIG. 6D. The tunnel isolation layer 77 may be a layer where charges are tunneled by Fowler-Nordheim (F-N) tunneling, and may include an insulating material, such as oxide or nitride.

A channel layer 78 may be formed on a sidewall of the tunnel isolation layer 77. The channel layer 78 may include a semiconductor material. According to an embodiment, the channel layer 78 may include a semiconductor material, such as silicon or germanium, or a nanostructure, such as nanodots, nanotubes, or graphene.

A core insulating layer 79 may then be formed to fill a central area of the hole. The core insulating layer 79 may include an insulating material such as an oxide layer.

FIG. 6J is a cross-sectional diagram at a first level h1-h1′ of FIG. 6I. FIG. 6K is a cross-sectional diagram at the second level h2-h2′ of FIG. 6I. Referring to FIGS. 6I, 6J, and 6K, a second isolation structure 80 may be formed through the core insulating layer 79, the channel layer 78, the tunnel isolation layer 77, the data storage layer 76, and the blocking insulating layer 75 in the first direction Z. The second isolation structure 80 may extend in the second direction X and be coupled to the first isolation structures 73.

An etch process may be performed to form a trench having a line shape which passes through the core insulating layer 79, the channel layer 78, the tunnel isolation layer 77, the data storage layer 76, the blocking insulating layer 75 in the first direction Z, and the trench may be filled with an insulating material, so that the second isolation structure 80 may be formed.

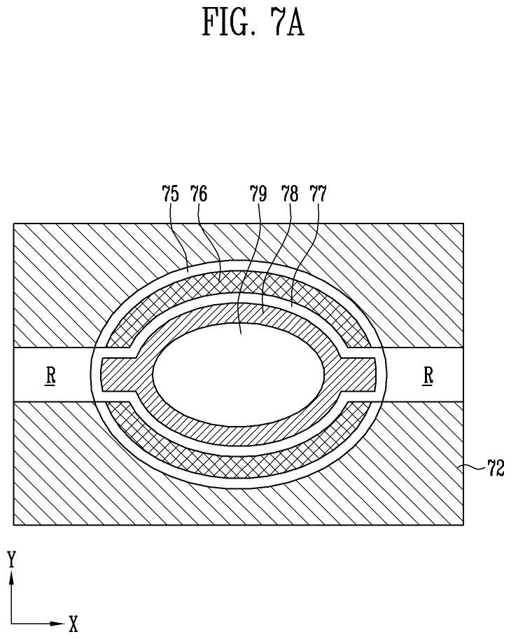

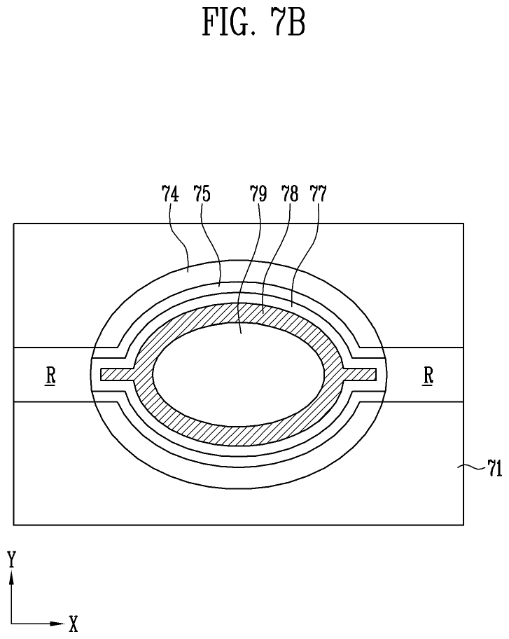

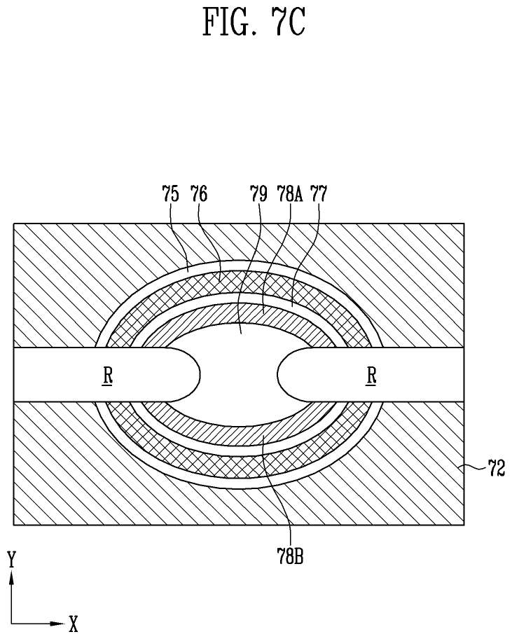

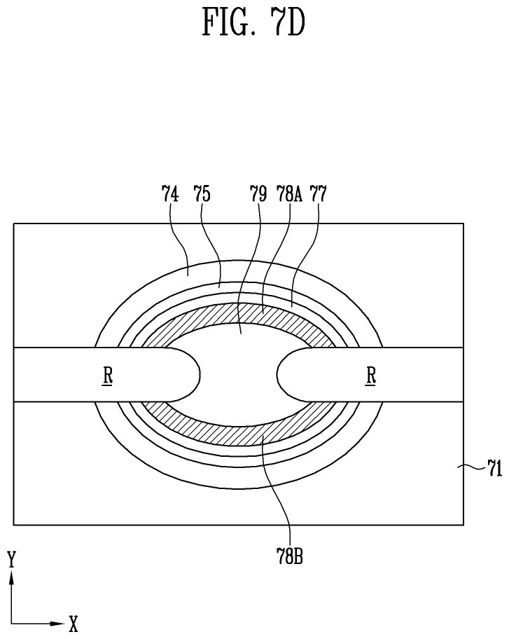

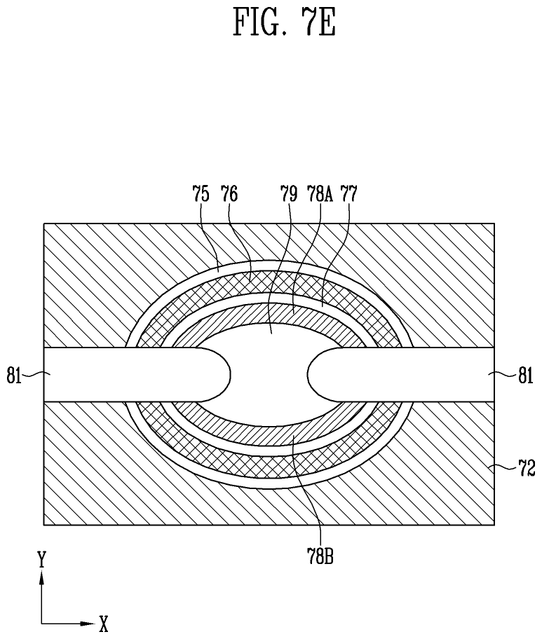

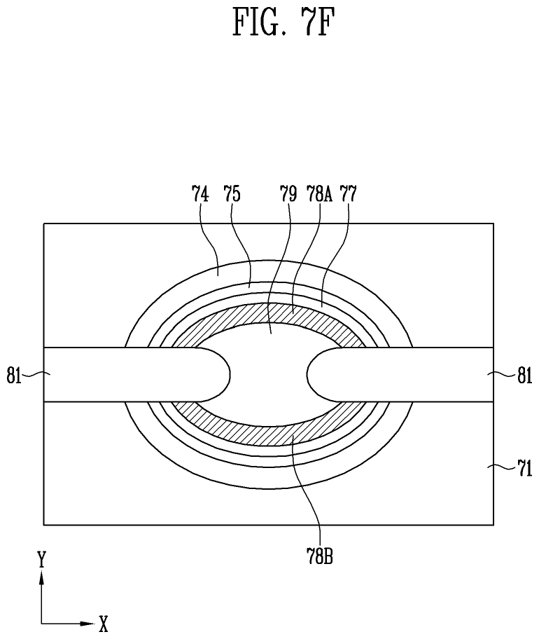

FIGS. 7A, 7B, 7C, 7D, 7E, and 7F are plan views for illustrating a method of manufacturing a semiconductor device according to an embodiment of the present disclosure.

A method of manufacturing a semiconductor device according to an embodiment of the present disclosure may include performing the processes as described above with reference to FIGS. 6A, 6B, 6C, 6D, 6E, 6F, 6G, and 6H and then performing the processes as described below with reference to FIGS. 7A, 7B, 7C, 7D, 7E, and 7F.

Descriptions about the processes shown in FIGS. 6A, 6B, 6C, 6D, 6E, 6F, 6G, and 6H will be omitted.

FIGS. 7A, 7C, and 7E are plan views at the level of the second material layers 72. FIGS. 7B, 7D, and 7F are plan views at the level of the first material layers 71.

Referring to FIGS. 7A and 7B, the recessed region R may be formed by performing an etch process to remove the first isolation structure 73 of FIGS. 6A and 6H. As a result, the tunnel isolation layer 77 at both sides of the second direction X may be exposed through the recessed region R.

Referring to FIGS. 7C and 7D, the channel layer 78 of FIGS. 7A and 7B may be exposed by etching a portion of the tunnel isolation layer 77 exposed through the recessed region R, and the exposed portion of the channel layer 78 may be etched to physically separate a first channel layer 78A and a second channel layer 78B from each other. Therefore, the first channel layer 78A and the second channel layer 78B may be separated from each other at both ends in the second direction X, and may have a symmetrical structure with respect to the third direction Y. The recessed region R may extend into the core insulating layer 79.

Referring to FIGS. 7E and 7F, a third isolation structure 81 may be formed by filling the recessed region R of FIGS. 7C and 7D with an insulating material.

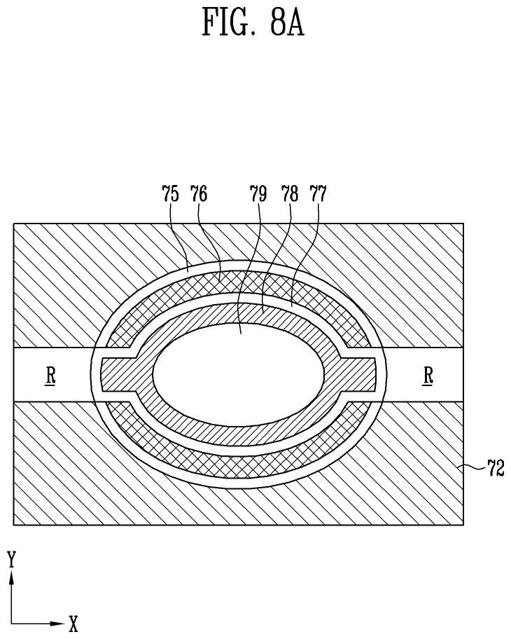

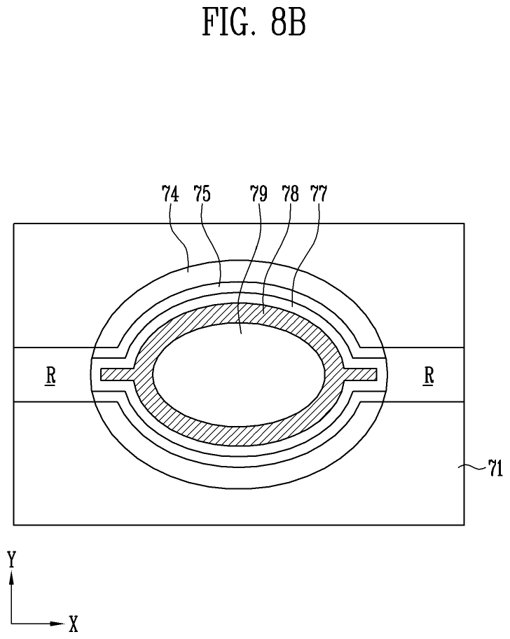

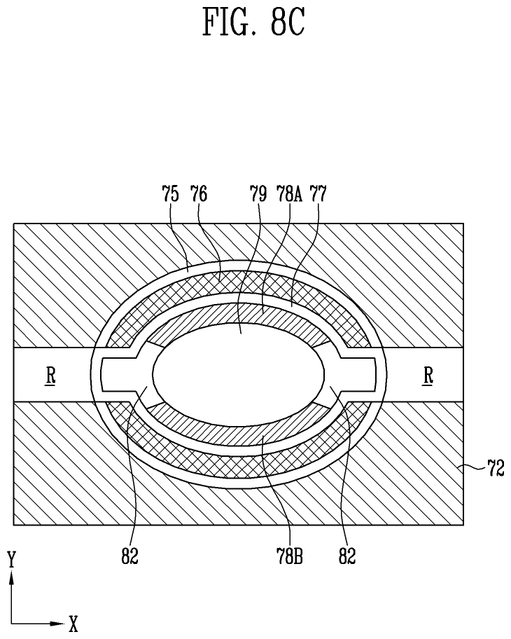

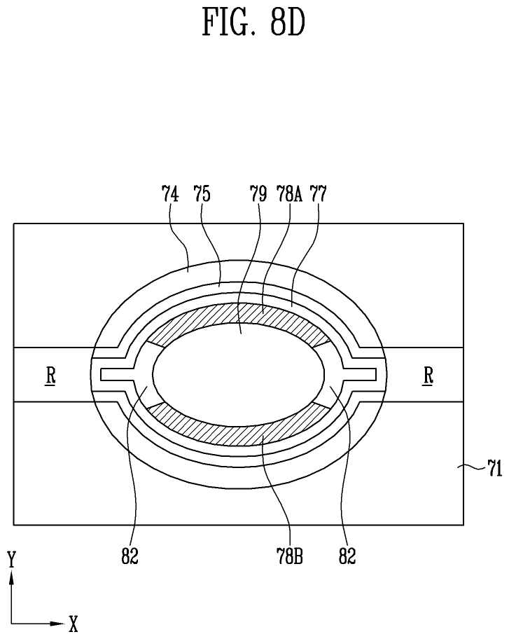

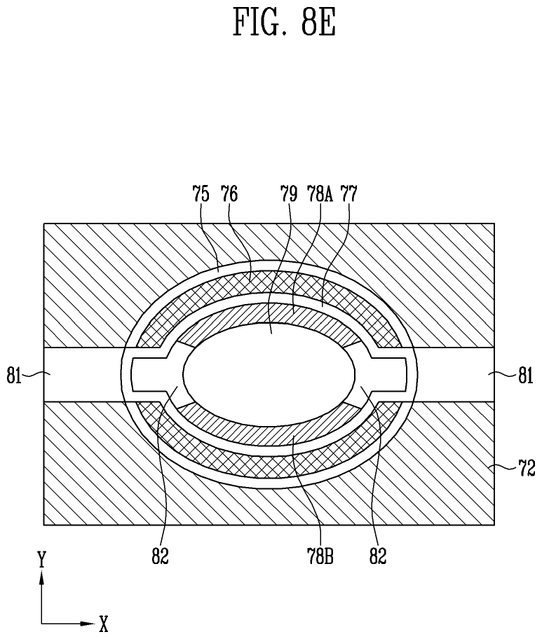

FIGS. 8A, 8B, 8C, 8D, 8E, and 8F are plan views for illustrating a method of manufacturing a semiconductor device according to an embodiment of the present disclosure.

A method of manufacturing a semiconductor device according to an embodiment of the present disclosure may include performing the processes as described above with reference to FIGS. 6A, 6B, 6C, 6D, 6E, 6F, 6G, and 6H and then performing the processes as described below with reference to FIGS. 8A, 8B, 8C, 8D, 8E, and 8F.

Descriptions about the processes shown in FIGS. 6A, 6B, 6C, 6D, 6E, 6F, 6G, and 6H will be omitted.

Referring to FIGS. 8A and 8B, an etch process may be performed to form the recessed region R by removing the first isolation structure 73 of FIGS. 6G and 6H. As a result, the tunnel isolation layer 77 at both sides in the second direction X may be exposed through the recessed region R.

Referring to FIGS. 8C and 8D, a wet etch oxidation process may be performed through the recessed region R to oxidize a channel layer adjacent to the recessed region R, so that a channel isolation structure 82 may be formed. As a result, the channel layer 78 of FIGS. 8An and 8B may be divided into a first channel layer 78A and a second channel layer 78B which are separated by the channel isolation structure 82. Therefore, the first channel layer 78A and the second channel layer 78B may be separated from each other at both ends in the second direction X, and may have a symmetrical structure with respect to the third direction Y.

Referring to FIGS. 8E and 8F, the third isolation structure 81 may be formed by filling the recessed region R of FIGS. 8C and 8D with an insulating material.

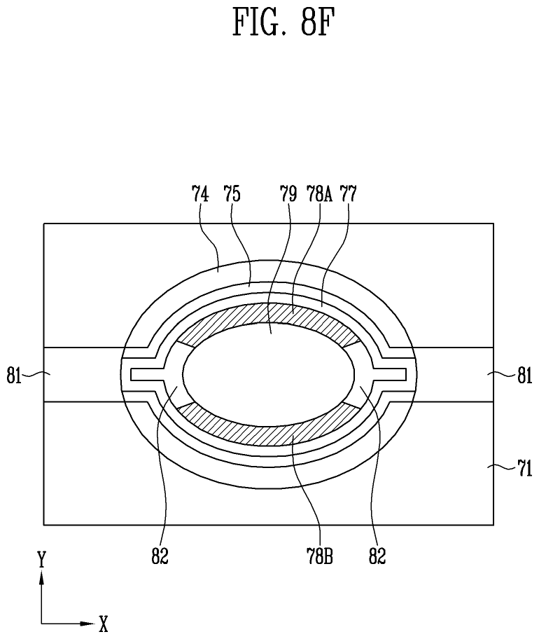

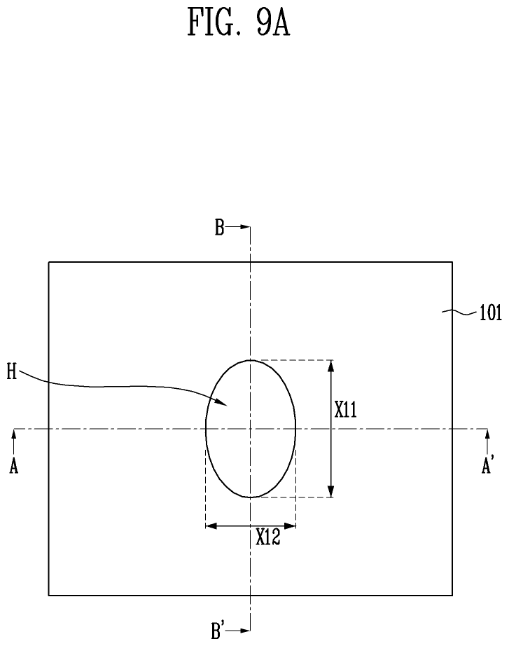

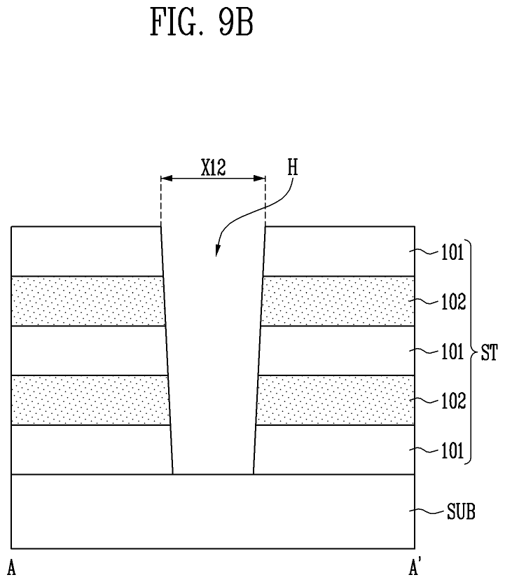

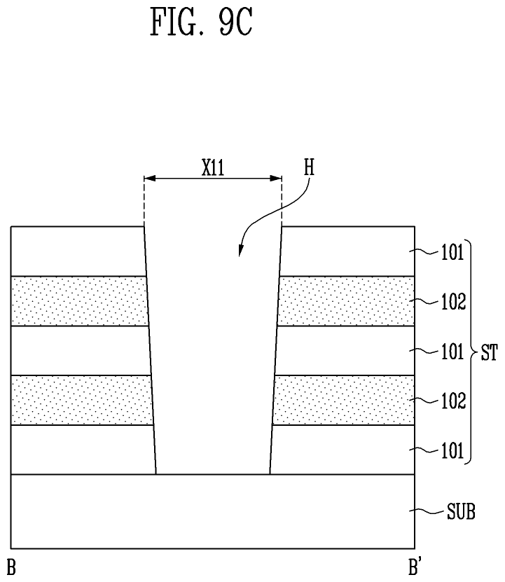

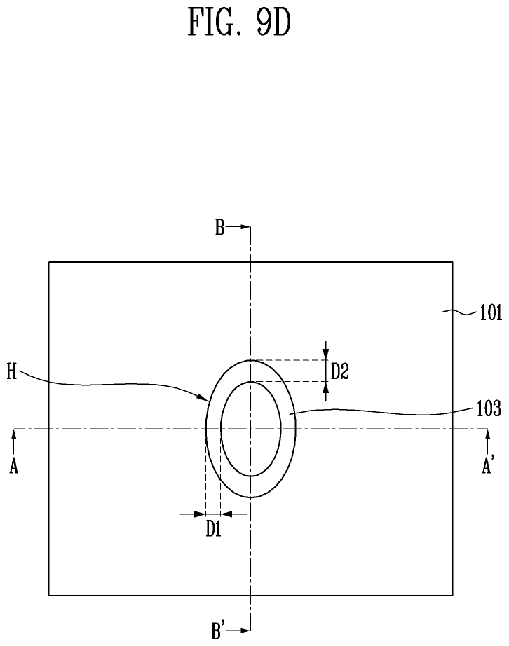

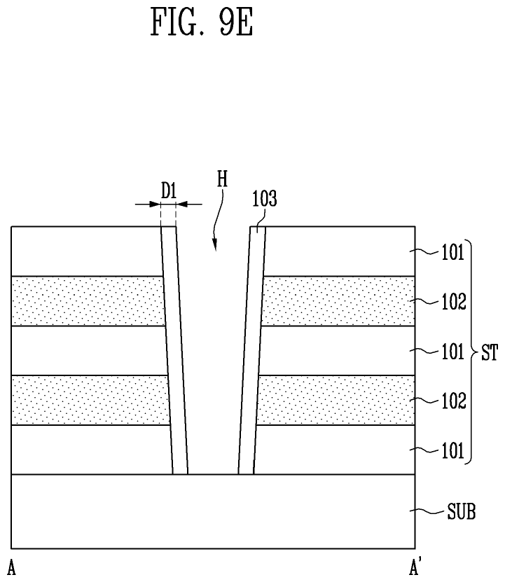

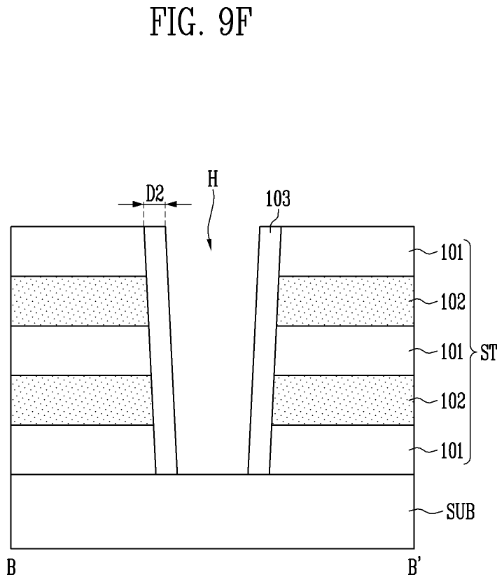

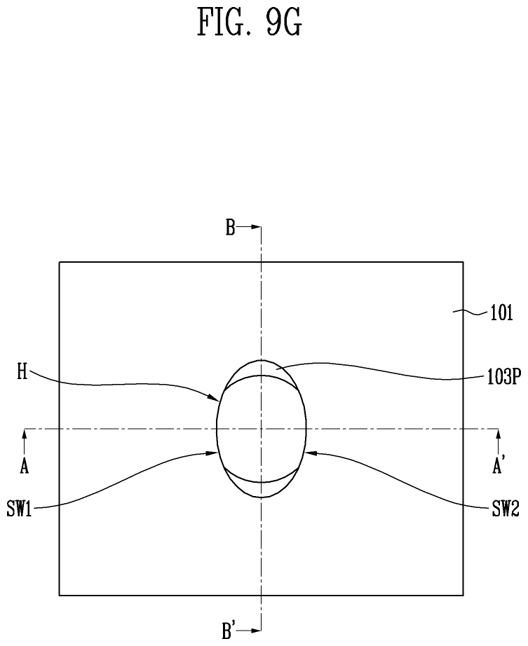

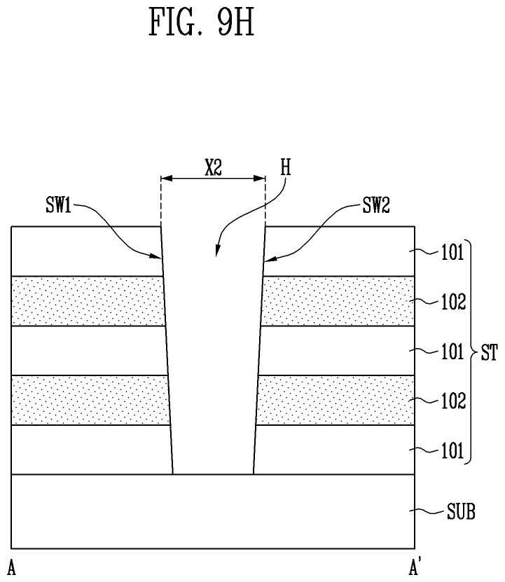

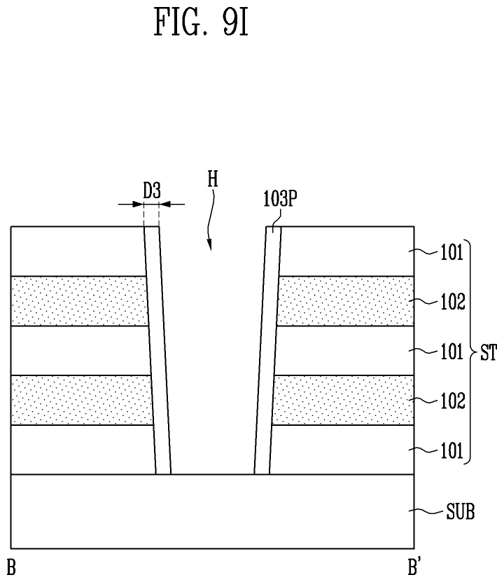

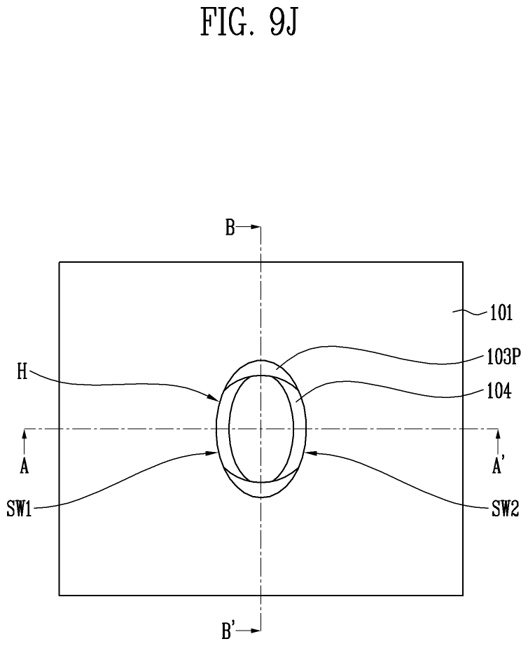

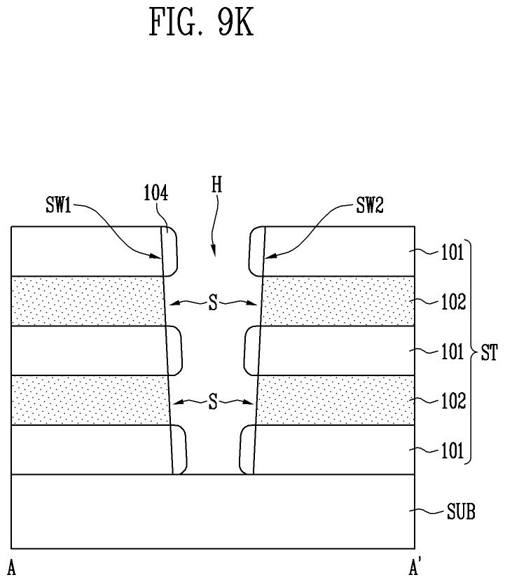

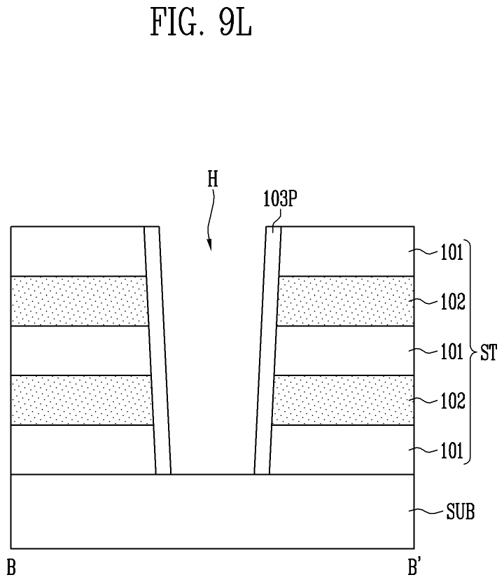

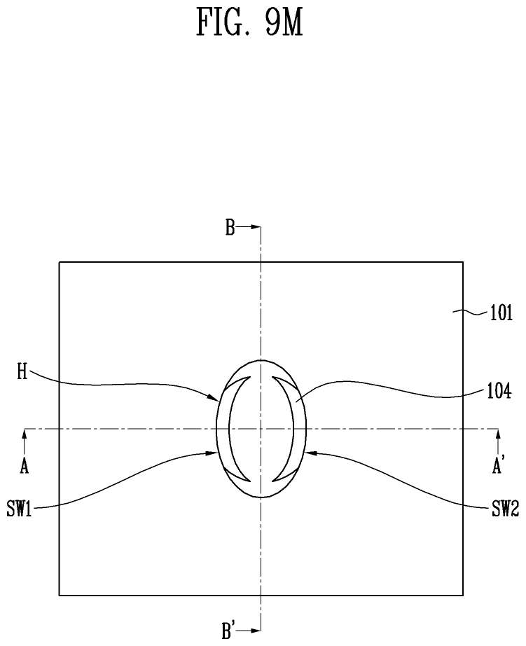

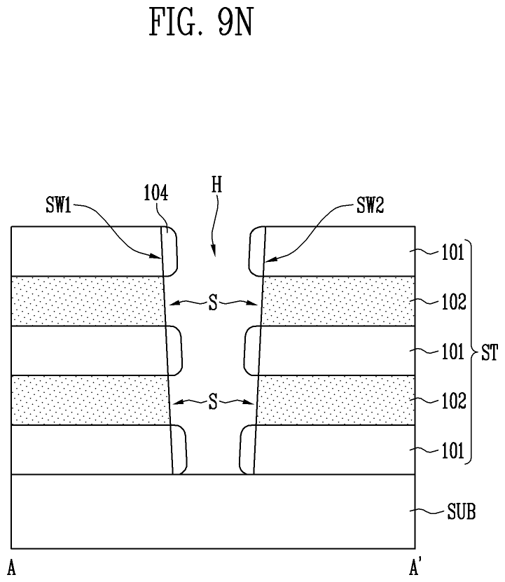

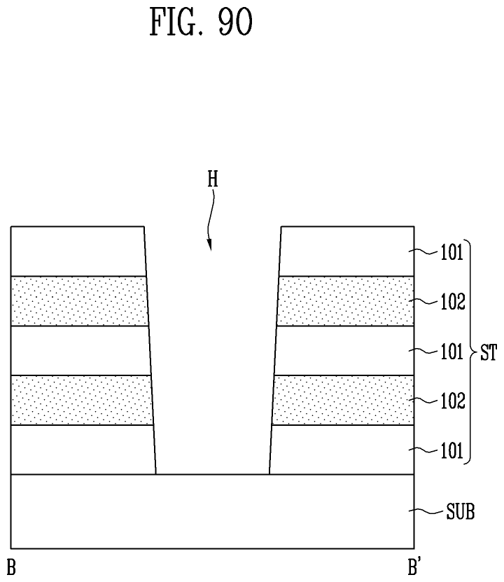

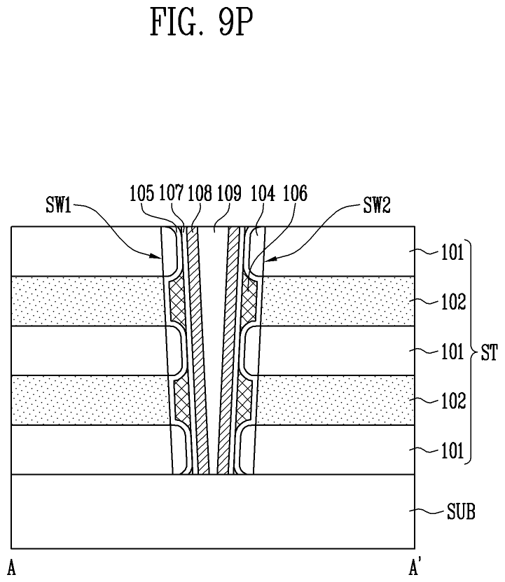

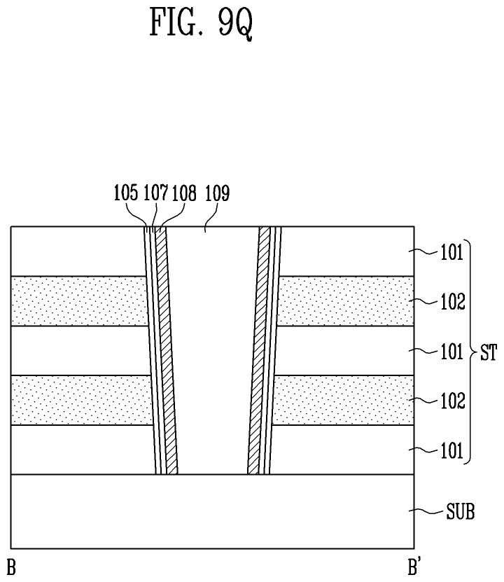

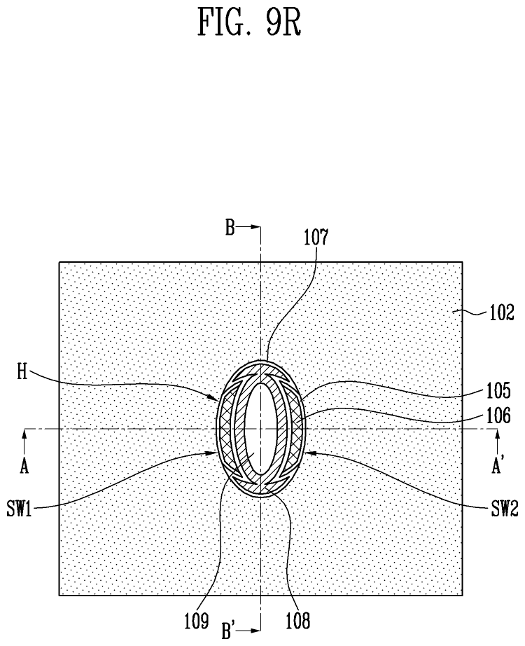

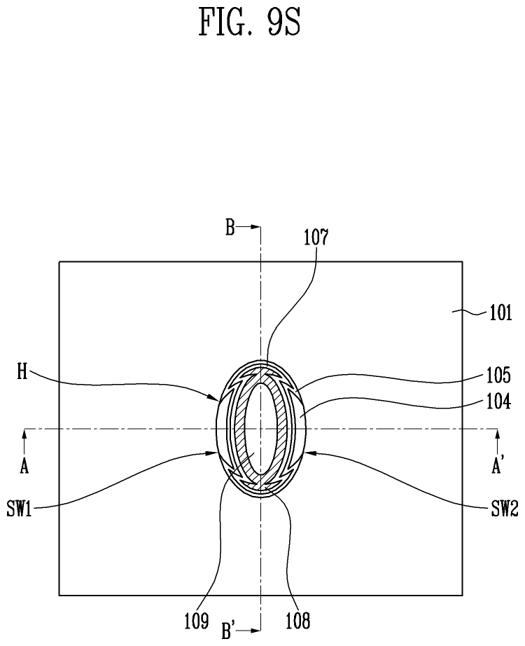

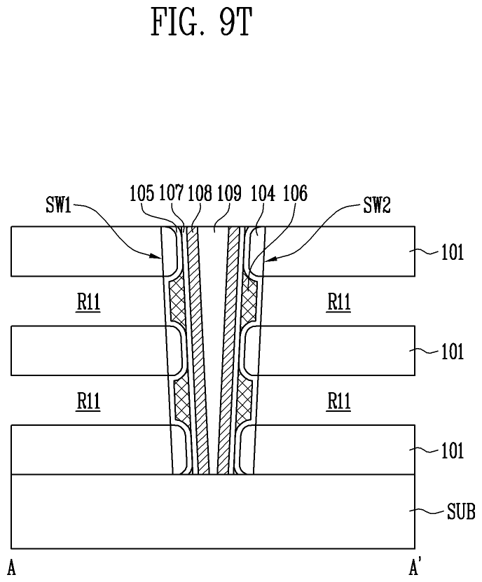

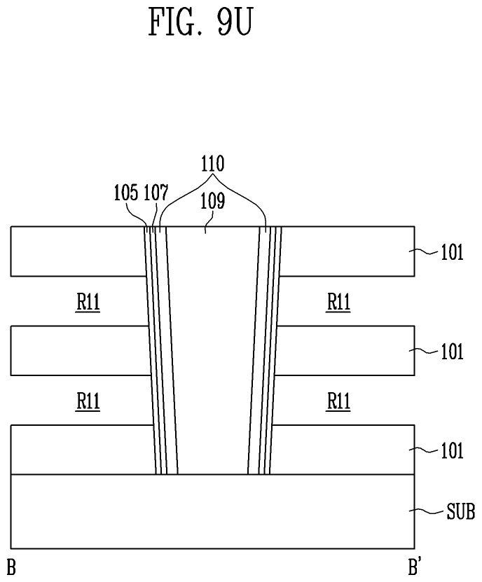

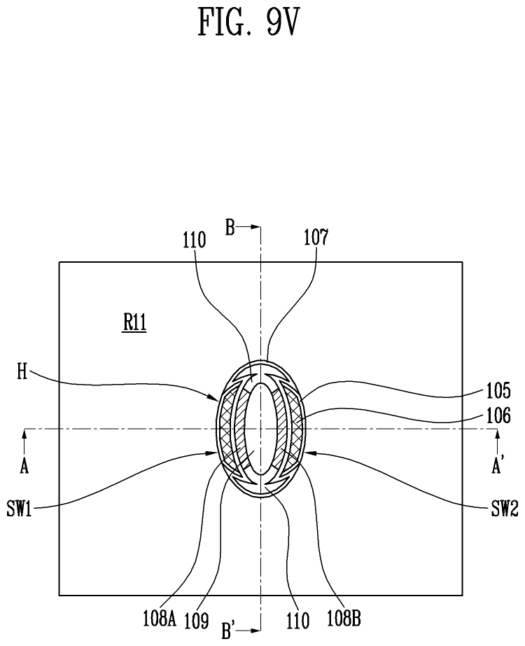

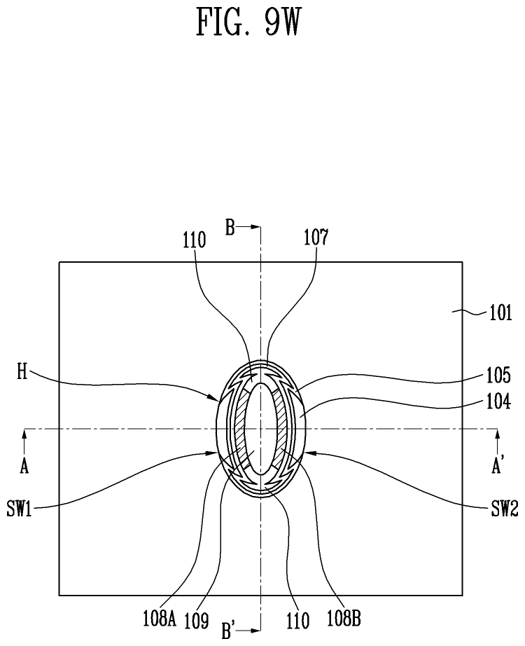

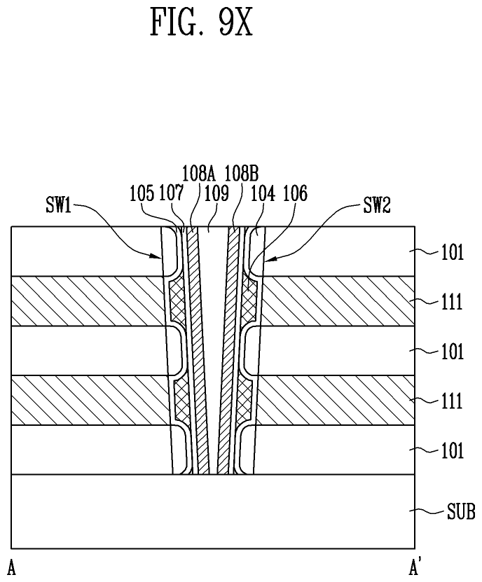

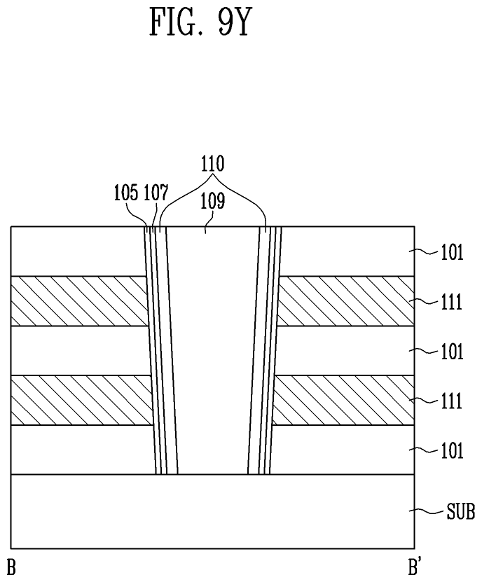

FIGS. 9A, 9B, 9C, 9D, 9E, 9F, 9G, 9H, 9I, 9J, 9K, 9L, 9M, 9N, 9O, 9P, 9Q, 9R, 9S, 9T, 9U, 9V, 9W, 9X, and 9Y are cross-sectional views and plan views for illustrating a method of manufacturing a semiconductor device according to an embodiment of the present disclosure.

Referring to FIGS. 9A, 9B, and 9C, the stacked structure ST may be formed on the substrate SUB. The stacked structure ST may include first material layers 101 and second material layers 102 that are staked alternately with each other. The first and second material layers 101 and 102 may be stacked in a vertical direction to the substrate SUB. The first and second material layers 101 and 102 may be formed using a deposition process such as chemical vapor deposition (CVD).

The first material layers 101 may include a material having a high etch selectivity with respect to the second material layers 102. For example, the first material layers 101 may include an insulating material such as oxide and the second material layers 102 may include a sacrificial material such as nitride. In another example, the first material layers 101 may include an insulating material such as oxide and the second material layers 102 may include a conductive material such as polysilicon and tungsten.

Subsequently, a hard mask pattern (not shown) may be formed on the stacked structure ST, and an etch process using the hard mask pattern may be performed to form the hole H which passes through at least a portion of the stacked structure ST. The hole H may be partially extended into the substrate SUB.

A width X12 of the hole H in a first horizontal direction A-A′ may be less than a width X11 of the hole H in a second horizontal direction B-B′. For example, the hole H may have an elliptical cross-section.

Referring to FIGS. 9D, 9E, and 9F, an insulating layer 103 may be formed on a sidewall of the hole H. The insulating layer 103 may be an oxide layer. The insulating layer 103 may include a silicon oxide. A thickness D1 of the insulating layer 103 formed on the sidewall of the hole H in the first horizontal direction A-A′ may be different from a thickness D2 of the insulating layer 103 formed on the sidewall of the hole H in the second horizontal direction B-B′. A thickness D1 of the insulating layer 103 formed on the sidewall of the hole H in the first horizontal direction A-A′ may be less than a thickness D2 of the insulating layer 103 formed on the sidewall of the hole H in the second horizontal direction B-B′.

Referring to FIGS. 9G, 9H, and 9I, by etching the insulating layer 103 in FIGS. 9D, 9E, and 9F to a predetermined thickness, a portion of the insulating layer may be removed. The etch process may be performed using an isotropic etch process. For example, a portion of the insulating layer 103 may be etched to expose the sidewall of the hole H in the first horizontal direction A-A′. During the etch process, since the thickness of the insulating layer 103 formed on the sidewall of the hole H in the first horizontal direction A-A′ is less than that of the insulating layer 103 formed on the sidewall of the hole H, the insulating layer 103 may remain on the sidewall of the hole H in the second horizontal direction B-B′ even when the insulating layer 103 is etched to expose the sidewall of the hole H in the first horizontal direction A-A′. In addition, an etch rate in the second horizontal direction B-B′ may be faster than an etch rate in the first horizontal direction A-A′ due to differences in surface area exposed by an etchant during the isotropic etch process and surface angle. As a result, a sacrificial pattern 103P may be formed on both sidewalls of the hole H in the second horizontal direction B-B′. A horizontal cross-section of the sacrificial pattern 103P may have a crescent shape. A thickness D3 of the sacrificial pattern 103P may be less than the thickness D2 of the insulating layer 103 in FIG. 9F which is formed on the sidewall of the insulating layer 103 in the second horizontal direction B-B′.

The sidewall of the hole H may be divided into a first sidewall SW1 and a second sidewall SW2 on the basis of the sacrificial pattern 103P. For example, both sides of the sidewall of the hole H in the first horizontal direction A-A′ may be divided into the first sidewall SW1 and the second sidewall SW2.

Referring to FIGS. 9J, 9K, and 9L, insulating patterns 104 may be formed on sidewalls of the first material layers 101 which are exposed through the hole H. The insulating patterns 104 may be separately formed on the first sidewall SW1 and the second sidewall SW2 on both sides in the first horizontal direction A-A′. The insulating patterns 104 formed on the first sidewall SW1 and the second sidewall SW2 may have a symmetrical structure such that the insulating patterns 104 may oppose each other. The insulating pattern 104 may be formed using a selective deposition process and include oxide.

As a result, the spaces S may be formed between the insulating patterns 104 adjacent to each other in the vertical direction. As a result, an irregular portion may be formed on the first sidewall SW1 and the second sidewall SW2 of the hole H.

Referring to FIGS. 9M, 9N, and 9O, the sacrificial pattern 103P of FIGS. 9J and 9I may be removed by performing an etch process. As a result, the irregular portion may be maintained on the first sidewall SW1 and the second sidewall SW2 of the hole H, and sidewalls of the first material layer 101 and the second material layer 102 may be exposed from both side portions of the hole H in the second horizontal direction B-B′.

Referring to FIGS. 9P, 9Q, 9R, and 9S, a blocking insulating layer 105 may be formed on the sidewall of the hole H in FIGS. 9M and 9N. The blocking insulating layer 105 on the first sidewall SW1 and the second sidewall SW2 of the hole H may be formed on the exposed surface of the insulating pattern 104 and the sidewalls of the second material layers 102. The blocking insulating layer 105 at both sides of the hole H in the second horizontal direction B-B′ may be formed on the sidewalls of the first material layer 101 and the second material layer 102. The blocking insulating layer 105 may include a high dielectric layer. For example, the blocking insulating layer 105 may include a high-k material such as aluminum oxide (Al₂O₃), hafnium oxide (HfOx), hafnium silicon oxide (HfSiOx), or the like.

Subsequently, a data storage layer 106 may be formed in the spaces S in FIG. 9N. For example, after the data storage layer 106 is formed on the sidewall of the blocking insulating layer 105, an etchback process may be performed such that the data storage layers 106 may remain only in the spaces S in FIG. 9N. As a result, the data storage layers 106 formed in the spaces S of FIG. 9N may be separated from each other in the vertical direction, and the data storage layers 106 formed on the first sidewall SW1 and the second sidewall SW2 of the hole may be separated from each other on both sides of the hole in the second horizontal direction.

The data storage layer 106 may include a charge trap material, a nitride, a variable resistance material, or a nanostructure, or a combination thereof.

Subsequently, a tunnel isolation layer 107 may be formed on the sidewall of the data storage layer 106 and the sidewall of the blocking insulating layer 105 which are exposed through the hole. The tunnel isolation layer 107 may be a layer where charges are tunneled by Fowler-Nordheim (F-N) tunneling, and may include an insulating material, such as oxide or nitride.

A channel layer 108 may be formed on a sidewall of the tunnel isolation layer 107. The channel layer 108 may include a semiconductor material. According to an embodiment, the channel layer 108 may include a semiconductor material, such as silicon or germanium, or a nanostructure, such as nanodots, nanotubes, or graphene.

A core insulating layer 109 may then be formed to fill a central area of the hole. The core insulating layer 109 may include an insulating material such as an oxide layer.

Referring to FIGS. 9T, 9U, 9V, and 9W, an etch process may be performed to expose the sidewall of the stacked structure ST of FIGS. 9P and 9Q, and the exposed portions of the second material layers 102 of FIGS. 9P and 9Q may be removed to form recessed regions R11.

Subsequently, a wet oxidation process may be performed through the recessed region R11 to oxidize a channel layer adjacent to the recessed region R11, so that a channel isolation structure 110 may be formed. The channel isolation structure 110 may be formed at both side portions in the second horizontal direction B-B′ where the data storage layer 106 is not formed. A channel layer adjacent to the data storage layer 106 may be divided into a first channel layer 108A and a second channel layer 108B by the channel isolation structure 110.

Subsequently, third material layers 60 may be formed in spaces from which the second material layers are removed. The third material layers 60 may include a conductive material such as polysilicon, tungsten, metal, or the like. The first material layers 51 and the third material layers 60 may be defined as the gate stacked structure GST.

Referring to FIGS. 9X and 9Y, third material layers 111 may be formed in the recessed region R11 of FIGS. 9T and 9U. The third material layers 111 may include a conductive material such as polysilicon, tungsten, metal, or the like. The first material layers 101 and the third material layers 111 may be defined as a gate stacked structure.

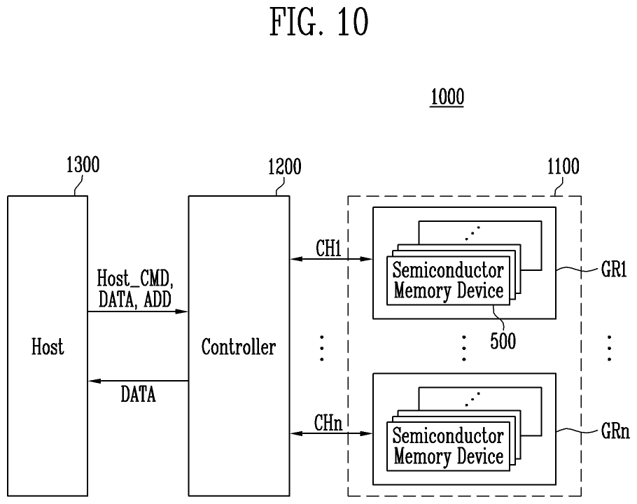

FIG. 10 is a block diagram illustrating a memory system 1000 including a semiconductor device according to an embodiment of the present disclosure.

Referring to FIG. 10, the memory system 1000 may include a memory device 1100, a controller 1200, and a host 1300. The memory device 1100 may include a plurality of semiconductor memory devices 500. The plurality of semiconductor memory devices 500 may be divided into a plurality of groups GR1 to GRn. According to an embodiment of the present disclosure, it is shown that the host 1300 is included in the memory system 1000. However, the memory system 1000 may include only the controller 1200 and the memory device 1100, and the host 1300 may be disposed outside the memory system 1000.

As shown in FIG. 10, the plurality of groups GR1 to GRn in the memory device 1100 may communicate with the controller 1200 through first to nth channels CH1 to CHn, respectively. Each of the semiconductor memory devices 500 may be the semiconductor device as described above with reference to FIGS. 1A, 1B, and 1C.

Each of the plurality of groups GR1 to GRn may be configured to communicate with the controller 1200 through a single common channel. The controller 1200 may be configured to control the plurality of semiconductor memory devices 500 of the memory device 1100 through the plurality of first to nth channels CH1 to CHn.

The controller 1200 may be coupled between the host 1300 and the memory device 1100. The controller 1200 may be configured to access the memory device 1100 in response to a request from the host 1300. For example, the controller 1200 may be configured to control read, write, erase, and background operations of the memory device 1100 in response to a host command Host_CMD which is received from the host 1300. The host 1300 may transfer an address ADD and data DATA to program along with the host command Host_CMD to the memory device 1100 during a program operation. During a read operation, the controller 1200 may transfer a command corresponding to the read operation to the memory device 1100, receive the read data DATA from the memory device, and transfer the transferred data DATA to the host 1300. The controller 1200 may be configured to provide an interface between the memory device 1100 and the host 1300. The controller 1200 may run firmware for controlling the memory device 1100.

The host 1300 may include portable electronic devices such as PDAs, PMPs, MP3 players, cameras, camcorders, or cellular phones. The host 1300 may request a program operation, a read operation, and an erase operation of the memory system 1000 through the host command Host_CMD. The host 1300 may transfer the host command Host_CMD corresponding to a program operation, the data DATA, and the address ADD for the program operation to the controller 1200. The host 1300 may transfer the host command Host_CMD corresponding to a read operation and the address ADD for the read operation to the controller 1200. The address ADD may be a logical address.

The controller 1200 and the memory device 1100 may be integrated in one semiconductor device. According to an exemplary embodiment, the controller 1200 and the memory device 1100 may be integrated into a single semiconductor device to form a memory card. For example, the controller 1200 and the memory device 1100 may be integrated into a single semiconductor device and form a memory card such as a PC card (personal computer memory card international association (PCMCIA)), a compact flash (CF) card, a smart media card (SM or SMC), a memory stick multimedia card (MMC, RS-MMC, or MMCmicro), a SD card (SD, miniSD, microSD, or SDHC), a universal flash storage (UFS), and the like.

In another example, the memory system 1000 may be provided as one of various elements of an electronic device such as a computer, a ultra-mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture player, a digital picture recorder, a digital video recorder, a device capable of transmitting/receiving information in an wireless environment, one of various devices for forming a home network, one of various electronic devices for forming a computer network, one of various electronic devices for forming a telematics network, an RFID device, or one of various elements for forming a computing system.

In an exemplary embodiment, the memory device 1100 or the memory system 1000 may be embedded in various forms of packages. For example, the memory device 1100 or the memory system 1000 may be mounted using packages such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSOP), thin small outline package (TSOP), system in package (SIP), multi chip package (MCP), wafer-level fabricated package (WFP), wafer-level processed stack package (WSP), and the like.

According to the present disclosure, in an embodiment, the number of memory cells may be increased by separating a plurality of plug patterns from each other by using an isolation pattern.

It will be apparent to those skilled in the art that various modifications can be made to the above-described embodiments without departing from the spirit or scope of the disclosure. Thus, it is intended that the embodiments cover all such modifications provided they come within the scope of the appended claims and their equivalents.

What is claimed is:

1. A semiconductor device, comprising:
a gate stacked structure including interlayer insulating layers and conductive layers stacked alternately with each other;
a first plug pattern and a second plug pattern extending in a vertical direction corresponding to a stacking direction of the gate stacked structure;
first data storage layers disposed between the first plug pattern and the conductive layers and second data storage layers disposed between the second plug pattern and the conductive layers;
an isolation structure extending in the vertical direction and separating the first plug pattern and the second plug pattern from each other; and
insulating patterns disposed between the first data storage layers adjacent to each other in the vertical direction and the second data storage layers adjacent to each other in the vertical direction.

2. The semiconductor device of claim 1, wherein the isolation structure extends in a horizontal direction substantially perpendicular to the vertical direction and spaces apart the first data storage layers and the second data storage layers from each other.

3. The semiconductor device of claim 1, wherein the insulating patterns are disposed between the interlayer insulating layers and the first plug pattern and between the interlayer insulating layers and the second plug pattern.

4. The semiconductor device of claim 1, wherein each of the first plug pattern and the second plug pattern comprises:
a core insulating layer extending in the vertical direction and including an inner sidewall contacting the isolation structure;
a channel layer contacting an outer sidewall of the core insulating layer; and
a tunnel isolation layer contacting an outer sidewall of the channel layer.

5. The semiconductor device of claim 1, further comprising a blocking insulating layer surrounding upper and lower surfaces of the first data storage layers and the second data storage layers and sidewalls of the first data storage layers and the second data storage layers adjacent to the conductive layers.

6. The semiconductor device of claim 5, wherein the blocking insulating layer surrounds the upper and lower surfaces of the insulating patterns and extends to interfaces between the insulating patterns and the first plug pattern and interfaces between the insulating patterns and the second plug pattern.

7. The semiconductor device of claim 1,
wherein the conductive layers protrude further than the interlayer insulating layers in a direction toward the first plug pattern, and
wherein the conductive layers protrude further than the insulating layers in a direction toward the second plug pattern.

8. A method of manufacturing a semiconductor device, the method comprising:
forming a hole passing through at least a portion of a stacked structure including first material layers and second material layers stacked alternately with each other;
forming recessed regions by etching sidewalls of the first material layers exposed through the hole to a predetermined thickness, and forming sacrificial patterns in the recessed regions;
forming insulating patterns protruding further than the sidewalls of the second material layers in a direction of the hole by oxidizing the sacrificial patterns;
forming a data storage layer in spaces between the insulating patterns adjacent to each other in a vertical direction;
forming a plug pattern extending in the vertical direction in the hole; and
forming an isolation structure passing through the plug pattern in the vertical direction and separating the plug pattern into a first plug pattern and a second plug pattern.

9. The method of claim 8, further comprising, before forming the data storage layer, forming a blocking insulating layer extending along sidewalls of the insulating patterns and the sidewalls of the second material layers exposed through the hole.

10. The method of claim 9, wherein the forming the plug pattern comprises:
forming a tunnel isolation layer on a sidewall of the data storage layer and a sidewall of the blocking insulating layer exposed through the hole;
forming a channel layer on a sidewall of the tunnel isolation layer; and
forming a core insulating layer by filling a central area of the hole with an insulating material.

11. The method of claim 9, wherein the forming the isolation structure comprises:
forming a trench having substantially a line shape passing through the plug pattern by performing an etch process; and
forming the isolation structure by filling the trench with an insulating material.

12. The method of claim 11, wherein the trench extends in a horizontal direction and passes through the data storage layer.

13. The method of claim 11, wherein the trench extends in a horizontal direction and passes through the data storage layer, the blocking insulating layer, and the conductive layers.

14. The method of claim 8, further comprising:
performing an etch process to expose a sidewall of the stacked structure;
removing exposed portions of the second material layers; and
filling third material layers in spaces from which the exposed portions of the second material layers are removed.

15. A method of manufacturing a semiconductor memory device, the method comprising:
forming a hole passing through at least a portion of a stacked structure including first material layers and second material layers stacked alternately with each other;
forming protruding patterns on sidewalls of the second material layers exposed through the hole;
forming insulating patterns protruding further than sidewalls of the protruding patterns in a direction of the hole in spaces between the protruding patterns adjacent to each other in a vertical direction;
forming a data storage layer in spaces between the insulating patterns adjacent to each other in the vertical direction;
forming a plug pattern extending in the vertical direction in the hole; and
forming an isolation structure passing through the plug pattern in the vertical direction and separating the plug pattern into a first plug pattern and a second plug pattern.

16. The method of claim 15, wherein the forming the insulating patterns comprises:
forming sacrificial patterns in the spaces between the protruding patterns; and
forming the insulating patterns protruding further than the sidewalls of the protruding patterns in the direction of the hole by oxidizing the sacrificial patterns.

17. The method of claim 15, further comprising, before forming the data storage layer, forming a blocking insulating layer extending on sidewalls of the insulating patterns and sidewalls of the second material layers exposed through the hole.

18. The method of claim 17, wherein the forming the plug pattern comprises:
forming a tunnel isolation layer on a sidewall of the data storage layer and a sidewall of the blocking insulating layer exposed through the hole;
forming a channel layer on a sidewall of the tunnel isolation layer; and
forming a core insulating layer by filling a central area of the hole with an insulating material.

19. The method of claim 18, wherein the trench extends in a horizontal direction and passes through the data storage layer.

20. The method of claim 18, wherein the trench extends in a horizontal direction and passes through the data storage layer, the blocking insulating layer, and the conductive layers.

21. The method of claim 15, further comprising:
performing an etch process to expose a sidewall of the stacked structure;
removing exposed portions of the second material layers and the protruding patterns; and
filling third material layers in spaces from which the exposed portions of the second material layers and the protruding patterns are removed.

22. A method of manufacturing a semiconductor device, the method comprising:
forming a hole passing through at least a portion of a stacked structure including first material layers and second material layers stacked alternately with each other;
forming insulating patterns on sidewalls of the first material layers exposed through the hole;
forming a data storage layer in spaces between the insulating patterns adjacent to each other in the vertical direction;
forming a plug pattern extending in the vertical direction in the hole; and
forming an isolation structure passing through the plug pattern in the vertical direction and separating the plug pattern into a first plug pattern and a second plug pattern.

23. The method of claim 22, wherein the forming the insulating patterns includes forming the insulating patterns protruding further than sidewalls of the second material layers in a direction of the hole by using a selective deposition process.

24. The method of claim 22, further comprising, before forming the data storage layer, forming a blocking insulating layer extending along sidewalls of the insulating patterns and sidewalls of the second material layers exposed through the hole.

25. The method of claim 24, wherein the forming the plug pattern comprises:
forming a tunnel isolation layer on a sidewall of the data storage layer and a sidewall of the blocking insulating layer exposed through the hole;
forming a channel layer on a sidewall of the tunnel isolation layer; and
forming a core insulating layer by filling a central area of the hole with an insulating material.

26. The method of claim 25, wherein the trench extends in a horizontal direction and passes through the data storage layer.

27. The method of claim 25, wherein the trench extends in a horizontal direction and passes through the data storage layer, the blocking insulating layer, and the conductive layers.

28. The method of claim 22, further comprising:
performing an etch process to expose a sidewall of the stacked structure;
removing exposed portions of the second material layers; and
filling third material layers in spaces from which the exposed portions of the second material layers are removed.

29. A method of manufacturing a semiconductor device, the method comprising:
forming a hole having substantially an elliptical shape passing through at least a portion of a stacked structure including first material layers and second material layers stacked alternately with each other;
forming recessed regions by etching sidewalls of the first material layers exposed through the hole to a predetermined thickness, and forming sacrificial patterns in the recessed regions;
forming insulating patterns protruding further than the sidewalls of the second material layers in a direction of the hole by oxidizing the sacrificial patterns;
forming a data storage layer in spaces between the insulating patterns adjacent to each other in the vertical direction;
sequentially forming a tunnel isolation layer and a channel layer extending in the vertical direction on a sidewall of the hole, wherein a thickness of a cross section of the channel layer in a first horizontal direction is greater than a thickness of a cross section in a second horizontal direction substantially perpendicular to the first horizontal direction;
forming a first channel layer and a second channel layer by etching the channel layer to a predetermined thickness so that the channel layer is divided into the first and second channel layers in the first horizontal direction, and exposing a portion of the tunnel isolation layer through and between the first channel layer and the second channel layer; and
sequentially etching an exposed portion of the tunnel isolation layer and the data storage layer to divide the tunnel isolation layer and the second isolation layer in two parts in the first horizontal direction.

30. The method of claim 29, further comprising forming an isolation pattern by filling a central area of the hole with an insulating material.

31. The method of claim 29, wherein a diameter of the hole in the first horizontal direction is greater than a diameter of the hole in the second horizontal direction.

32. The method of claim 29, wherein the first channel layer and the second channel layer have substantially symmetrical crescent shapes opposing each other in the second horizontal direction.

33. The method of claim 29, further comprising:
performing an etch process to expose a sidewall of the stacked structure;
removing exposed portions of the second material layers; and
filling third material layers in spaces from which the exposed portions of the second material layers are removed.

34. A method of manufacturing a semiconductor device, the method comprising:
forming a stacked structure including first material layers and second material layers stacked alternately with each other;
forming a first isolation pattern passing through the stacked structure in a vertical direction and extending in a first horizontal direction;
forming a hole passing through the stacked structure and the first isolation pattern;
forming recessed regions by etching sidewalls of the first material layers exposed through the hole to a predetermined thickness, and forming sacrificial patterns in the recessed regions;
forming insulating patterns protruding further than sidewalls of the second material layers in a direction of the hole by oxidizing the sacrificial patterns;
forming a data storage layer in spaces between the insulating patterns adjacent to each other in the vertical direction;
sequentially forming a tunnel isolation layer, a channel layer, and a core insulating layer extending in the vertical direction on a sidewall of the hole; and
forming a second isolation pattern passing through the tunnel isolation layer, the channel layer, and the core insulating in the vertical direction and separating the channel layer into a first channel layer and a second channel layer.

35. The method of claim 34, further comprising, before forming the data storage layer, forming a blocking insulating layer extending along sidewalls of the insulating patterns and sidewalls of the second material layers exposed through the hole.

36. The method of claim 34, wherein the forming the second isolation pattern compress:
forming a trench having a line shape extending in the first horizontal direction and exposing a sidewall of the first isolation pattern by performing an etch process; and
a second isolation pattern by filling the trench with an insulating material.

37. A method of manufacturing a semiconductor device, the method comprising:
forming a stacked structure including first material layers and second material layers stacked alternately with each other;
forming a first isolation pattern passing through the stacked structure in a vertical direction and extending in a first horizontal direction;
forming a hole passing through the stacked structure and the first isolation pattern;
forming first recessed regions by etching sidewalls of the first material layers exposed through the hole to a predetermined thickness and forming sacrificial patterns in the first recessed regions;
forming insulating patterns protruding further than sidewalls of the second material layers in a direction of the hole by oxidizing the sacrificial patterns;
forming a data storage layer in spaces between the insulating patterns adjacent to each other in the vertical direction;
sequentially forming a tunnel isolation layer, a channel layer, and a core insulating layer extending in the vertical direction on a sidewall of the hole;
forming a second recessed region by removing the first isolation pattern; and
separating the channel layer into a first channel layer and a second channel layer spaced apart from each other by etching the tunnel isolation layer and the channel layer exposed through the second recessed region.

38. The method of claim 37, further comprising forming an isolation structure by filling the second recessed region with an insulating material.

39. The method of claim 37, further comprising, before forming the data storage layer, forming a blocking insulating layer extending along the sidewalls of the insulating patterns and the sidewalls of the second material layers exposed through the hole.

40. A method of manufacturing a semiconductor device, the method comprising:
forming a stacked structure including first material layers and second material layers stacked alternately with each other;
forming a first isolation pattern passing through the stacked structure in a vertical direction and extending in a first horizontal direction;
forming a hole passing through the stacked structure and the first isolation pattern;
forming first recessed regions by etching sidewalls of the first material layers exposed through the hole to a predetermined thickness, and forming sacrificial patterns in the first recessed regions;
forming insulating patterns protruding further than the sidewalls of the second material layers in a direction of the hole by oxidizing the sacrificial patterns;
forming a data storage layer in spaces between the insulating patterns adjacent to each other in the vertical direction;
sequentially forming a tunnel isolation layer, a channel layer, and a core insulating layer extending in the vertical direction on a sidewall of the hole;
forming a second recessed region by removing the first isolation pattern; and
forming a channel isolation structure by oxidizing a portion of the channel layer adjacent to the second recessed region by performing a wet oxidation process through the second recessed region.

41. The method of claim 40, wherein the channel layer is separated into a first channel layer and a second channel layer and spaced apart from each other by the channel isolation structure.

42. The method of claim 40, further comprising forming an isolation structure by filling the second recessed region with an insulating material.

43. A method of manufacturing a semiconductor device, the method comprising:
forming a hole passing through at least a portion of a stacked structure including first material layers and second material layers stacked alternately with each other;
forming a first isolation pattern and a second isolation pattern contacting an interface between a first sidewall and a second sidewall opposing each other in the hole, and extending in a vertical direction;
forming insulating patterns on sidewalls of the first material layers exposed through the hole;
removing the first isolation pattern and the second isolation pattern and forming a data storage layer in spaces between the insulating patterns adjacent to each other in the vertical direction on the first and second sidewalls;
sequentially forming a tunnel isolation layer, a channel layer, and a core insulating layer on a sidewall of the hole;
performing an etch process to expose a sidewall of the stacked structure;
forming recessed regions by removing exposed portions of the second material layers; and
forming a channel isolation structure by oxidizing a portion of the channel layer adjacent to the recessed regions by performing a wet oxidation process through the recessed regions.

44. The method of claim 43, wherein the channel layer is separated into a first channel layer and a second channel layer by the channel isolation structure.

45. The method of claim 43, further comprising filling the recessed regions with a third material layer.
